(19) United States
(12) Patent Application Publication
(10) Pub. No.: US 2026/0250543 A1
(43) Pub. Date: Aug. 27, 2026

(54) PROTECTIVE FILM-FORMING COMPOSITION

(71) Applicant: NISSAN CHEMICAL CORPORATION, Tokyo (JP)

(72) Inventors: Tokio NISHITA, Toyama-shi (JP); Takumi TANAKA, Toyama-shi (JP)

(73) Assignee: NISSAN CHEMICAL CORPORATION, Tokyo (JP)

(21) Appl. No.: 19/162,741

(22) PCT Filed: Mar. 8, 2024
(86) PCT No.: PCT/JP2024/008927

§ 371 Date: Sep. 5, 2025

(30) Foreign Application Priority Data
Mar. 9, 2023 (JP) 2023-036566

(51) Int. Cl. C09D 163/00; C08K 5/10; C08K 5/3445; C08K 5/3492; C09D 7/20; C09D 7/63; G03F 7/11; G03F 7/16; H10P 50/68; H10P 76/20

(52) U.S. Cl. CPC C09D 163/00; C08K 5/10; C08K 5/3445; C08K 5/34922; C09D 7/20; C09D 7/63; G03F 7/11; G03F 7/168; H10P 50/683; H10P 76/204

(57) ABSTRACT

A protective film-forming composition for a semiconductor wet etching solution including: component (A): a film-forming component; component (B): a compound having an aromatic ring to which an acyloxy group is directly bonded; and component (C); a solvent.

### TECHNICAL FIELD

The present invention relates to a composition for forming a protective film excellent in resistance particularly to a semiconductor wet etching solution in a lithography process in semiconductor manufacturing. The present invention also relates to a protective film formed of the composition, a method for manufacturing a substrate with a resist pattern to which the protective film is applied, and a method for manufacturing a semiconductor device.

### BACKGROUND ART

In semiconductor manufacturing, a lithography process of providing a resist underlayer film between a substrate and a resist film formed on the substrate and forming a resist pattern having a desired shape is widely known. The substrate is processed after the resist pattern is formed, and dry etching is mainly used as the process, but wet etching may be used depending on the type of substrate. Patent Literature 1 discloses a resist underlayer film material having resistance to alkaline hydrogen peroxide water.

### CITATION LIST

### Patent Literature

Patent Literature 1: JP 2018-173520 A

### SUMMARY OF INVENTION

### Technical Problem

In a case where a protective film for a semiconductor substrate is formed by using a protective film-forming composition, and a base substrate is processed by wet etching, with the protective film used as an etching mask, the protective film is required to have a good masking function (that is, the masked part can protect the substrate) against a semiconductor wet etching solution.

The present invention has been made in view of the above circumstances, and an object thereof is to provide a protective film-forming composition that enables the formation of a protective film excellent in resistance to a semiconductor wet etching solution.

### Solution to Problem

As a result of intensive studies to solve the above-described problems, the present inventors have found that the above-described problems can be solved by including a specific component (B) in a protective film-forming composition, and have completed the present invention.

That is, the present invention includes the following aspects.
[1] A protective film-forming composition for a semiconductor wet etching solution including:
component (A); a film-forming component;
component (B): a compound having an aromatic ring to which an acyloxy group is directly bonded; and
component (C): a solvent.
[2] The protective film-forming composition according to [1], wherein the component (B) is a compound having an aromatic ring in which two or more acyloxy groups are directly bonded.
[3] The protective film-forming composition according to [1] or [2], wherein the component (B) is a compound having two or more aromatic rings in which two or more acyloxy groups are directly bonded.
[4] The protective film-forming composition according to any one of [1] to [3], wherein the acyloxy group has 2 to 4 carbon atoms.
[5] The protective film-forming composition according to any one of [1] to [4], wherein the aromatic ring is an aromatic hydrocarbon ring.
[6] The protective film-forming composition according to any one of [1] to [5], wherein the component (B) is represented by the following Formula (X-1) or (X-2):

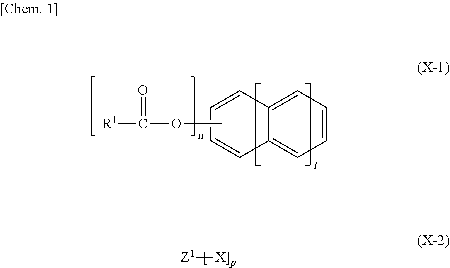

wherein in Formula (X-1), R¹ represents an alkyl group having 1 to 3 carbon atoms, t represents 0 or 1, u represents an integer of 1 to 4, and when there are two or more R¹'s, the two or more R¹'s may be the same or different,
in Formula (X-2), Z¹ represents a p-valent group, p represents an integer of 2 to 4, and X's each independently represent an organic group represented by the following Formula (X-2-1);

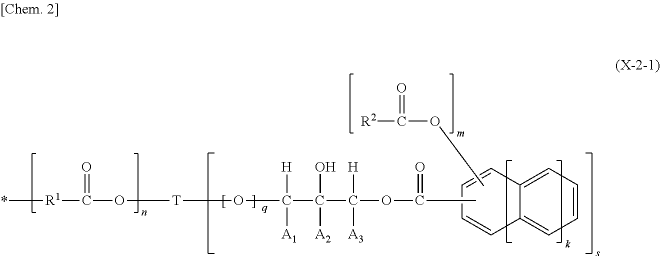

wherein in Formula (X-2-1), R¹ represents a single bond or an alkylene group having 1 to 4 carbon atoms,
R² represents an alkyl group having 1 to 3 carbon atoms,
T represents a single bond or a (s+1)-valent hydrocarbon group having 1 to 8 carbon atoms,
A₁ to A₃ each independently represent a hydrogen atom, a methyl group, or an ethyl group,
k represents 0 or 1,
m represents an integer of 1 to 4,
n represents 0 or 1,
q represents 0 or 1,
s represents 1 or 2,
when there are two or more R²'s, the two or more R²'s may be the same or different, and
* represents a bonding moiety to Z¹ in Formula (X-2),
provided that when T is a single bond, n and q are not simultaneously 1.
[7] The protective film-forming composition according to [6], wherein Z¹ in Formula (X-2) is represented by the following Formulae (X-2-2) to (X-2-6):

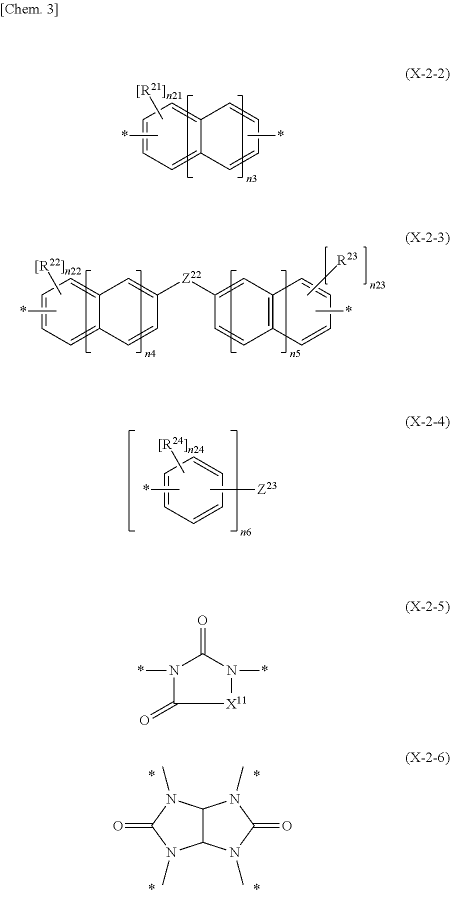

wherein in Formulae (X-2-2) to (X-2-4), R²¹ to R²⁴ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms,
in Formula (X-2-2), n3 represents 0 or 1, when n3 is 0, n21 represents an integer of 0 to 4, when n3 is 1, n21 represents an integer of 0 to 6, and when there are two or more R²¹'s, the two or more R²¹'s may be the same or different,
in Formula (X-2-3), Z²² represents a single bond, an oxygen atom, a sulfur atom, a carbonyl group, a sulfonyl group, or an alkylene group having 1 to 6 carbon atoms, n4 and n5 each independently represent 0 or 1, when n4 is 0, n22 represents an integer of 0 to 4, when n4 is 1, n22 represents an integer of 0 to 6, when there are two or more R²²'s, the two or more R²²'s may be the same or different, when n5 is 0, n23 represents an integer of 0 to 4, when n5 is 1, n23 represents an integer of 0 to 6, and when there are two or more R²³'s, the two or more R²³'s may be the same or different,
in Formula (X-2-4), n6 represents 3 or 4, Z²³ represents a n6-valent group, n24's each independently represent an integer of 0 to 4, a plurality of R²⁴'s may be the same or different,
in Formula (X-2-5), X¹¹ represents a group represented by the following Formula (X-2-5-1), the following Formula (X-2-5-2), the following Formula (X-2-5-3), or the following Formula (X-2-5-4), and
* represents a bond to X in Formula (X-2),

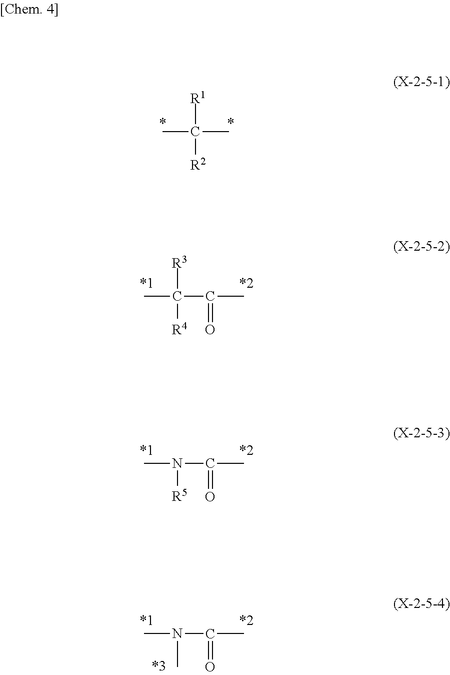

wherein in Formulae (X-2-5-1) to (X-2-5-4),
R¹ to R⁵ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent functional group selected from the group consisting of an alkyl group having 1 to 6 carbon atoms, a halogen atom, an alkoxy group having 1 to 10 carbon atoms, a nitro group, a cyano group, and an alkylthio group having 1 to 6 carbon atoms,
* represents a bond, *1 represents a bond bonded to a carbon atom in Formula (X-2-5), *2 represents a bond bonded to a nitrogen atom in Formula (X-2-5), and *3 represents a bond to X in Formula (X-2),
[8] The protective film-forming composition according to any one of [1] to [7], wherein the component (A) includes a polymer having at least one of a partial structure represented by the following Formula (1), a partial structure represented by the following Formula (2), and a partial structure represented by the following Formula (3):

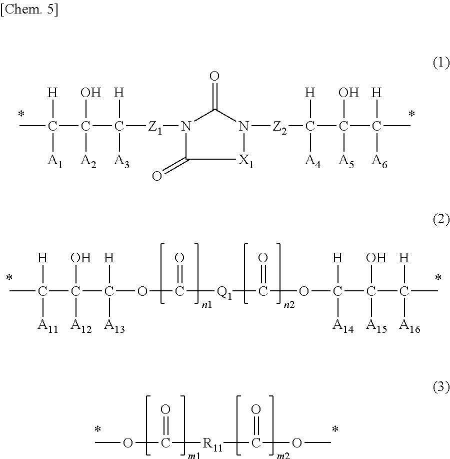

wherein in Formula (1), X₁ represents a divalent group represented by the following Formula (1-1), the following Formula (1-2), or the following Formula (1-3), Z₁ and Z₂ each independently represent a direct bond or a divalent group represented by the following Formula (1-4), A₁, A₂, A₃, A₄, A₅, and A₆ each independently represent a hydrogen atom, a methyl group, or an ethyl group, and * represents a bond,
in Formula (2), Q₁ represents a divalent organic group having an aromatic hydrocarbon ring or an aliphatic hydrocarbon ring, A₁₁, A₁₂, A₁₃, A₁₄; A₁₅, and Ais each independently represent a hydrogen atom, a methyl group, or an ethyl group, n1 and n2 each independently represent 0 or 1, and * represents a bond, and
in Formula (3), Ru represents an organic group having 1 to 30 carbon atoms, m1 and m2 each independently represent 0 or 1, and * represents a bond,

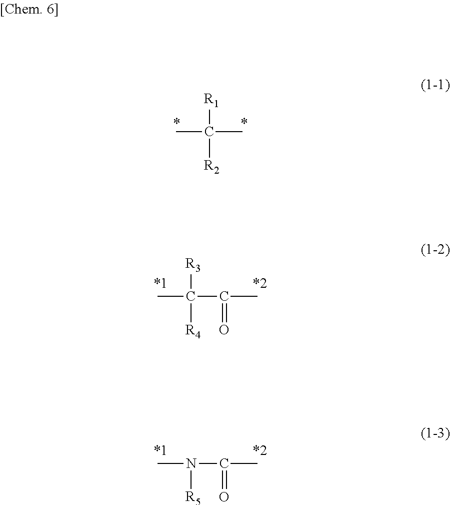

wherein in Formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded to each other to form a ring having 3 to 6 carbon atoms, R₃ and R₄ may be bonded to each other to form a ring having 3 to 6 carbon atoms, * represents a bond, *1 represents a bond bonded to a carbon atom, and *2 represents a bond bonded to a nitrogen atom,

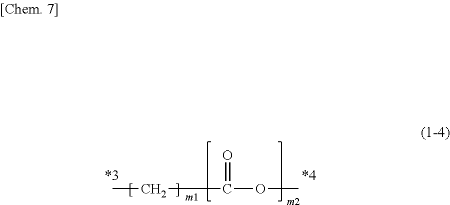

wherein in Formula (1-4), m1 is an integer of 1 to 4, and m2 is 0 or 1, *3 represents a bond bonded to a nitrogen atom, and *4 represents a bond bonded to a carbon atom.
[9] A protective film against a semiconductor wet etching solution, wherein the protective film includes a baked product of a coating film formed of the protective film-forming composition according to any one of [1] to [8].
[10] A method for manufacturing a substrate with a protective film which is used in semiconductor manufacturing, the method including: applying the protective film-forming composition according to any one of [1] to [8] onto a stepped semiconductor substrate and baking the composition to form a protective film, in which the method is used for manufacturing a semiconductor,
[11] A method for manufacturing a substrate with a resist pattern used in semiconductor manufacturing, the method including:
a step of applying the protective film-forming composition according to any one of [1] to [8] on a semiconductor substrate and baking the protective film-forming composition to form a protective film as a resist underlayer film; and
a step of forming a resist film directly on the protective film or over the protective film, with another layer interlayered, and exposing and developing the resist film to form a resist pattern.
[12] A method for manufacturing a semiconductor device, the method including a step of forming a protective film by using the protective film-forming composition according to any one of [1] to [8] on a semiconductor substrate having a surface on which an inorganic film is formed, forming a resist pattern directly on the protective film or over the protective film, with another layer interlayered, dry etching the protective film by using the resist pattern as a mask to expose a surface of the inorganic film, and performing wet etching on the inorganic film by using the protective film after the dry etching as a mask with a semiconductor wet etching solution.

### Advantageous Effects of Invention

According to the present invention, it is possible to provide the protective film-forming composition that enables the formation of the protective film excellent in resistance to the semiconductor wet etching solution.

### DESCRIPTION OF EMBODIMENTS

### (Protective Film-Forming Composition)

A protective film-forming composition of the present invention is a protective film-forming composition.

The protective film is preferably a protective film that protects an inorganic film formed on a surface of a semiconductor substrate from wet etching.

The protective film-forming composition contains a component (A), a component (B), and a component (C): a solvent.

The component (A) is a film-forming component.

The component (B) is a compound having an aromatic ring to which an acyloxy group is directly bonded.

The component (C) is a solvent.

### <Component (A)>

The component (A) is a film-forming component. The film-forming component refers to a component other than the component (B) and the component (C) in the protective film-forming composition.

The film-forming component includes, for example, an organic compound. The organic compound may be a low molecular compound or a high-molecular-weight compound (polymer).

Examples of such an organic compound include the following compounds.
A compound having a group represented by Formula (1) in the protective film-forming composition described in WO 2017/191767 A at a side chain or a terminal and having a weight average molecular weight of 800 or more
A compound represented by Formula (1a) or Formula (1b), or a compound having a substituent represented by Formula (2) and having a molecular weight of 300 or more and less than 800 or having a weight average molecular weight of 300 or more and less than 800 in the protective film-forming composition described in WO 2018/052130 A
A resin in the protective film-forming composition described in WO 2018/203464 A (for example, polyester, polyether, polyether ether ketone, novolac resin, maleimide resin, acrylic resin, and methacrylic resin)
A compound containing at least one set of two hydroxyl groups adjacent to each other in the molecule in the protective film-forming composition described in WO 2019/124474 A, or a polymer thereof
A compound containing at least one acetal structure in the molecule in the protective film-forming composition described in WO 2019/124475 A, or a polymer thereof
A ring-opening polymer (C) obtained by reaction of a diepoxy compound (A) with a di- or higher functional proton generating compound (B) in the protective film-forming composition described in WO 2020/090950 A
A compound or polymer containing at least one acetal structure and at least one amide structure in the protective film-forming composition described in WO 2020/153278 A

The contents of these publications are incorporated herein by reference to the same extent as if fully set forth.

The polymer is not particularly limited, but preferably contains a polymer having at least one of a partial structure represented by the following Formula (1), a partial structure represented by the following Formula (2), and a partial structure represented by the following Formula (3) (hereinafter, it may be referred to as a “polymer (A)”).

The polymer (A) preferably has a partial structure represented by the following Formula (1), a partial structure represented by the following Formula (2), and a partial structure represented by the following Formula (3).

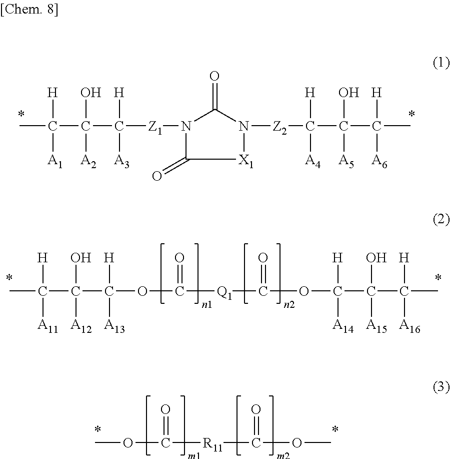

wherein in Formula (1), X₁ represents a divalent group represented by the following Formula (1-1), the following Formula (1-2), or the following Formula (1-3), Z₁ and Z₂ each independently represent a direct bond or a divalent group represented by the following Formula (1-4), A₁, A₂, A₃, A₄, A₅, and A₆ each independently represent a hydrogen atom, a methyl group, or an ethyl group, and * represents a bond,
in Formula (2), Q₁ represents a divalent organic group having an aromatic hydrocarbon ring or an aliphatic hydrocarbon ring, A₁₁, A₁₂, A₁₃, A₁₄, A₁₅, and A₁₆ each independently represent a hydrogen atom, a methyl group, or an ethyl group, n1 and n2 each independently represent 0 or 1, and * represents a bond, and
in Formula (3), Ru represents an organic group having 1 to 30 carbon atoms, m1 and m2 each independently represent 0 or 1, and * represents a bond,

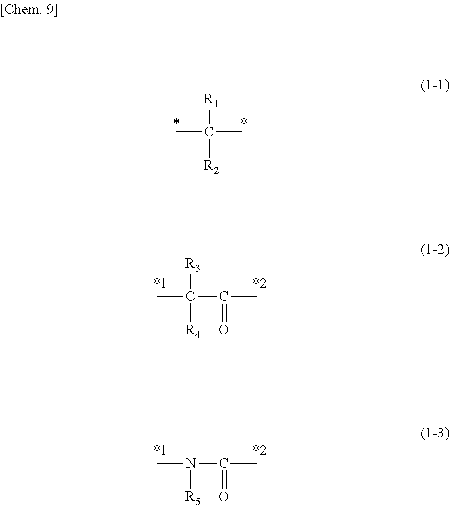

wherein in Formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded to each other to form a ring having 3 to 6 carbon atoms, R₃ and R⁴ may be bonded to each other to form a ring having 3 to 6 carbon atoms, * represents a bond, *1 represents a bond bonded to a carbon atom, and *2 represents a bond bonded to a nitrogen atom,

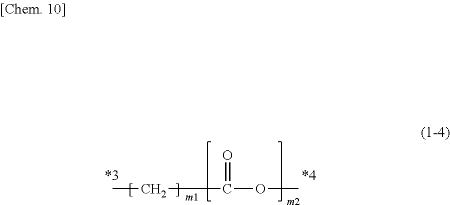

wherein in Formula (1-4), m1 is an integer of 1 to 4, and m2 is 0 or 1, *3 represents a bond bonded to a nitrogen atom, and *4 represents a bond bonded to a carbon atom.

Examples of the alkyl group having 1 to 10 carbon atoms and optionally interrupted by an oxygen atom or a sulfur atom in R₁ to R₅ in Formulae (1-1) to (1-3) include an alkyl group having 1 to 10 carbon atoms, an alkoxy group having 1 to 10 carbon atoms, an alkoxyalkyl group having 2 to 10 carbon atoms, an alkoxyalkoxyalkyl group having 3 to 10 carbon atoms, an alkylthio group having 1 to 10 carbon atoms, and an alkylthioalkyl group having 2 to 10 carbon atoms.

The alkyl group having 1 to 10 carbon atoms that are optionally interrupted by an oxygen atom or a sulfur atom may contain two or more oxygen atoms or sulfur atoms.

### <<X_{1>>}

X₁ in Formula (1) is preferably represented by Formula (1-3) from the viewpoint of suitably obtaining the effect of the present invention.

Examples of the structure represented by the following (1A) in Formula (1) include:

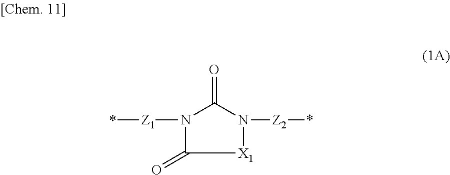

wherein in Formula (1A), Z₁, Z₂ and X₁ are the same as Z₁, Z₂ and X₁ in Formula (1), respectively, and * represents a bond. Examples thereof include structures exemplified below.

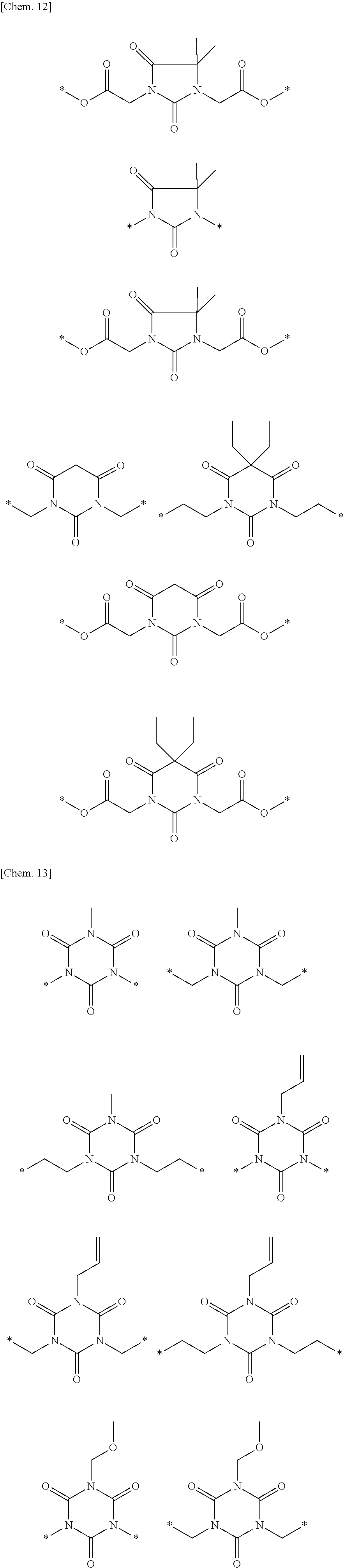

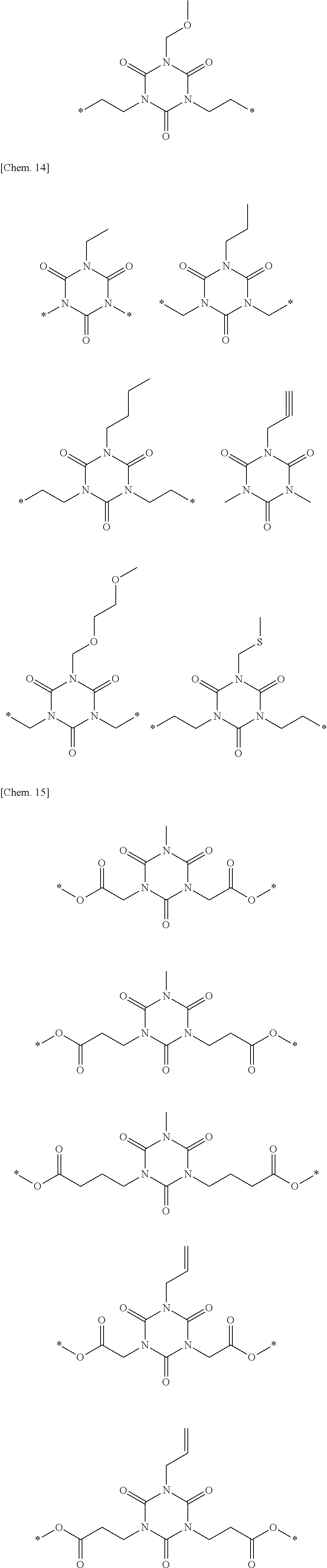

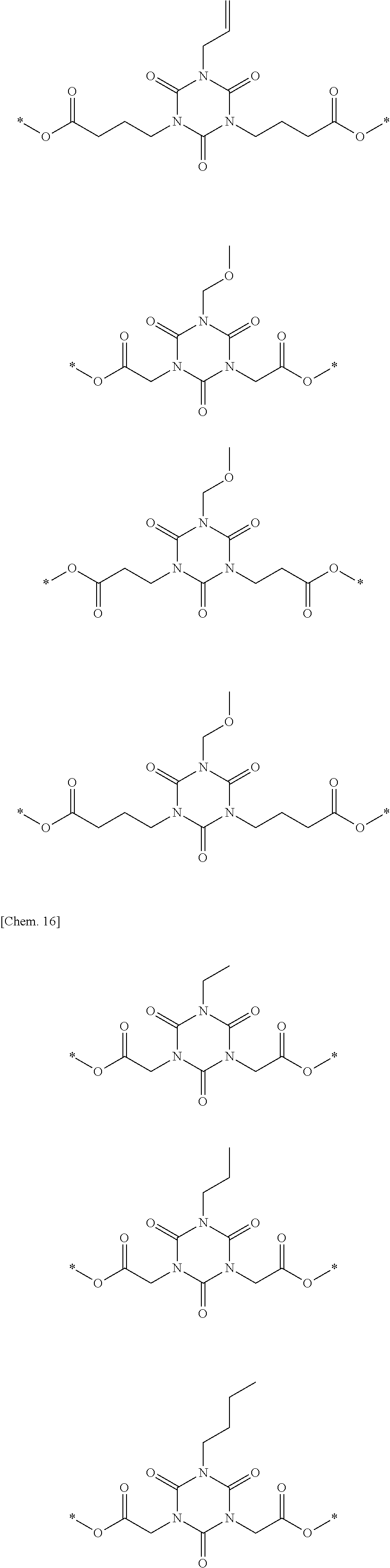

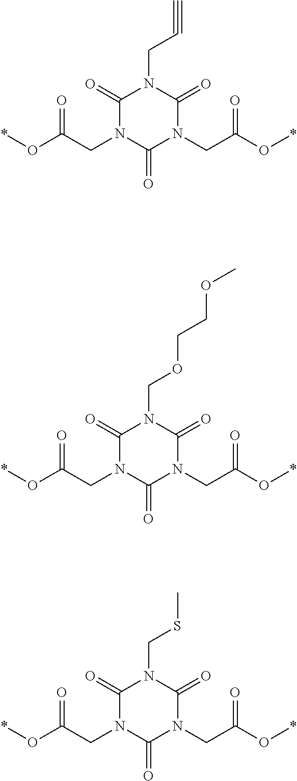 [SMILES: *OC(=O)Cn1c(=O)n(CC#C)c(=O)n(CC(=O)O*)c1=O ; *OC(=O)Cn1c(=O)n(COCCOC)c(=O)n(CC(=O)O*)c1=O ; *OC(=O)Cn1c(=O)n(CSC)c(=O)n(CC(=O)O*)c1=O]

In the above structures, * represents a bond.

### <<Q_{1>>}

Q₁ in Formula (2) is preferably represented by any one of the following Formulae (2-1) to (2-4) from the viewpoint of suitably obtaining the effect of the present invention.

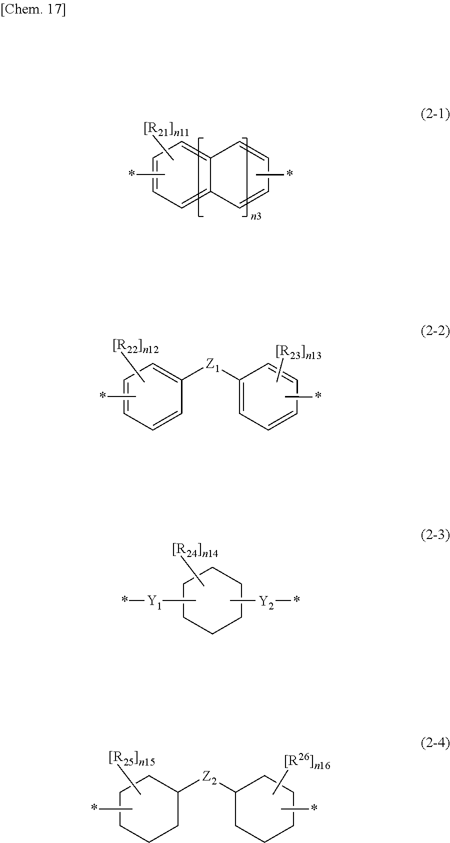

In Formulae (2-1) to (2-4), R₂₁ to R₂₆ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms, * represents a bond,
in Formula (2-1), n3 represents 0 or 1, when n3 is 0, n11 represents an integer of 0 to 4, when n3 is 1, n11 represents an integer of 0 to 6, and when there are two or more R₂₁'s, the two or more R₂₁'s may be the same or different,
in Formula (2-2), Z₁ represents a single bond, an oxygen atom, a sulfur atom, a carbonyl group, a sulfonyl group, or an alkylene group having 1 to 6 carbon atoms, n12 and n13 each independently represent an integer of 0 to 4, when there are two or more R₂₂'s, the two or more R₂₂'s may be the same or different, and when there are two or more R₂₃'s, the two or more R₂₃'s may be the same or different,
in Formula (2-3), Y₁ and Y₂ each independently represent a single bond or an alkylene group having 1 to 6 carbon atoms, n14 represents an integer of 0 to 4, and when there are two or more R₂₄'s, the two or more R₂₄'s may be the same or different,
in Formula (2-4), Z₂ represents a single bond, an oxygen atom, a sulfur atom, a carbonyl group, a sulfonyl group, or an alkylene group having 1 to 6 carbon atoms, n15 and n16 each independently represent an integer of 0 to 4, when there are two or more Ras's, the two or more R₂₅'s may be the same or different, and when there are two or more R₂₆'s, the two or more R₂₆'s may be the same or different.

In the present description, examples of the halogen atom include a fluorine atom, a chlorine atom, a bromine atom, and an iodine atom.

In the present description, the alkyl group is not limited to a linear alkyl group, and may be branched or cyclic. Examples of the linear or branched alkyl group include a methyl group, an ethyl group, an isopropyl group, a tert-butyl group, and a n-hexyl group. Examples of the cyclic alkyl group (cycloalkyl group) include a cyclobutyl group, a cyclopentyl group, and a cyclohexyl group.

In the present description, examples of the alkoxy group include a methoxy group, an ethoxy group, a n-pentyloxy group, and an isopropoxy group.

In the present description, examples of the alkylthio group include a methylthio group, an ethylthio group, a n-pentylthio group, and an isopropylthio group.

In the present description, examples of the alkenyl group include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, and a 2-methyl-2-propenyl group.

In the present description, examples of the alkynyl group include a group in which a double bond of an alkenyl group listed above as the “alkenyl group” is replaced with a triple bond.

In the present description, examples of the alkenyloxy group include a vinyloxy group, a 1-propenyloxy group, a 2-n-propenyloxy group (allyloxy group), a 1-n-butenyloxy group, and a prenyloxy group.

In the present description, examples of the alkynyloxy group include a 2-propynyloxy group, a 1-methyl-2-propynyloxy group, a 2-methyl-2-propynyloxy group, a 2-butynyloxy group, and a 3-butynyloxy group.

In the present description, examples of the acyl group include an acetyl group and a propionyl group.

In the present description, examples of the aryloxy group include a phenoxy group and naphthyloxy.

In the present description, examples of the arylcarbonyl group include a phenylcarbonyl group.

In the present description, examples of the aralkyl group include a benzyl group and a phenethyl group.

In the present description, examples of the alkylene group include a methylene group, an ethylene group, a 1,3-propylene group, a 2,2-propylene group, a 1-methylethylene group, a 1,4-butylene group, a 1-ethylethylene group, a 1-methylpropylene group, a 2-methylpropylene group, a 1,5-pentylene group, a 1-methylbutylene group, a 2-methylbutylene group, a 1,1-dimethylpropylene group, a 1,2-dimethylpropylene group, a 1-ethylpropylene group, a 2-ethylpropylene group, a 1,6-hexylene group, a 1,4-cyclohexylene group, a 1,8-octylene group, a 2-ethyloctylene group, a 1,9-nonylene group, and a 1,10-decylene group.

Examples of the structure represented by the following (2A) in Formula (2) include:

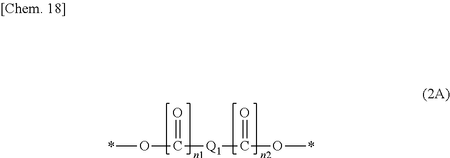

wherein in Formula (2A), Q₁, n1, and n2 are the same as Q₁, n1, and n2 in Formula (2), respectively, and * represents a bond. Examples thereof include structures exemplified below.

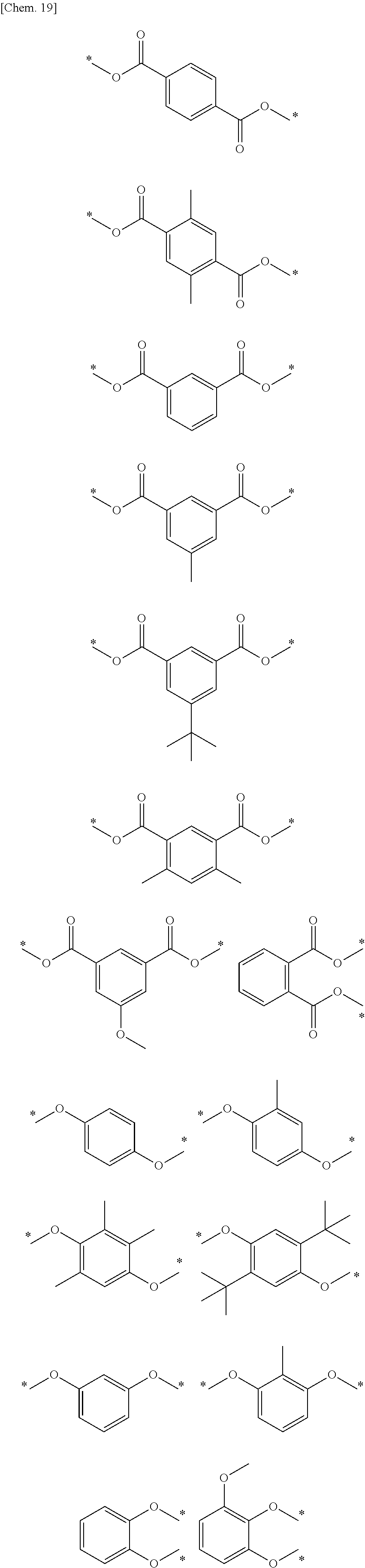

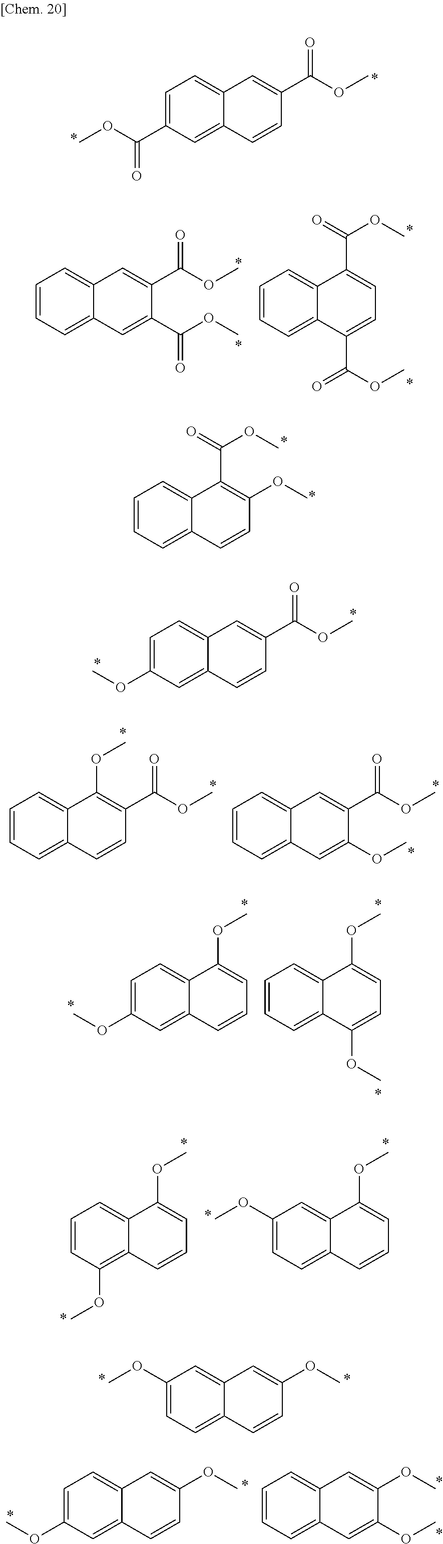

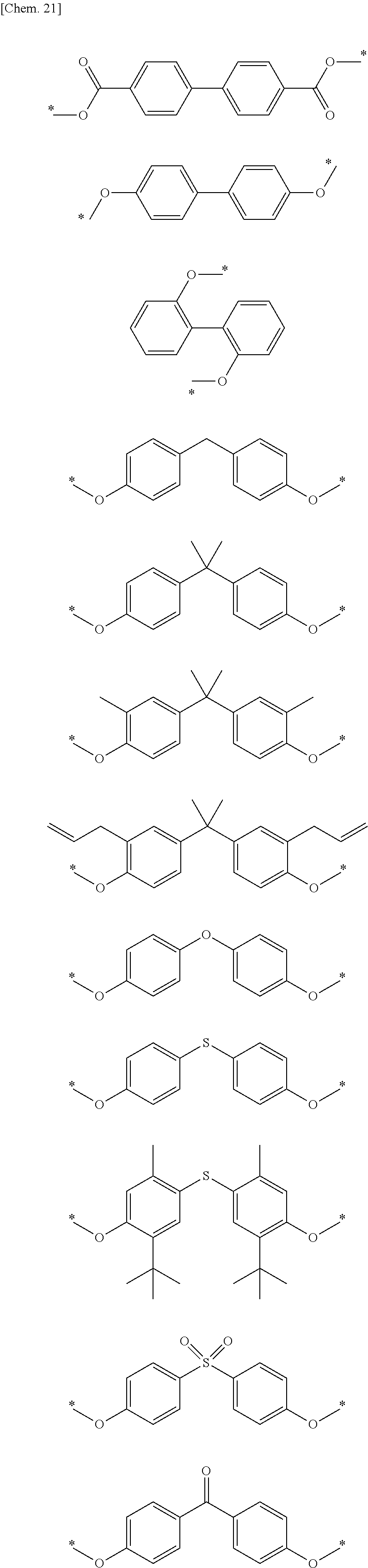

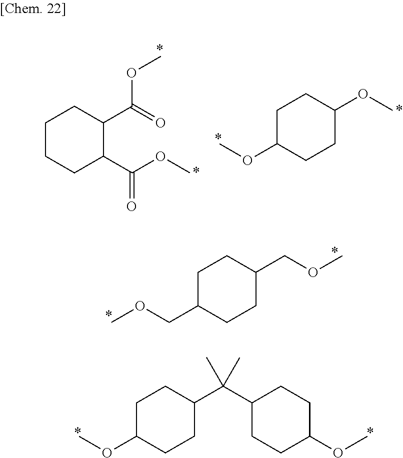

In the above structures, * represents a bond.

The organic group having 1 to 30 carbon atoms of R₁₁ in Formula (3) may have, for example, an aromatic ring or may not have an aromatic ring. Examples of the aromatic ring include an aromatic hydrocarbon ring and an aromatic heterocyclic ring.

The organic group having 1 to 30 carbon atoms of R₁₁ in Formula (3) may have, for example, an aliphatic ring or may not have an aliphatic ring.

The organic group having 1 to 30 carbon atoms of R₁₁ in Formula (3) may have, for example, an unsaturated bond or may not have an unsaturated bond.

Examples of the organic group having 1 to 30 carbon atoms of Ru in Formula (3) include an alkylene group having 1 to 10 carbon atoms, which may be interrupted by an oxygen atom or a sulfur atom. The alkylene group having 1 to 10 carbon atoms that are optionally interrupted by an oxygen atom or a sulfur atom may contain two or more oxygen atoms or sulfur atoms.

Examples of the partial structure represented by Formula (3) include the following structures.

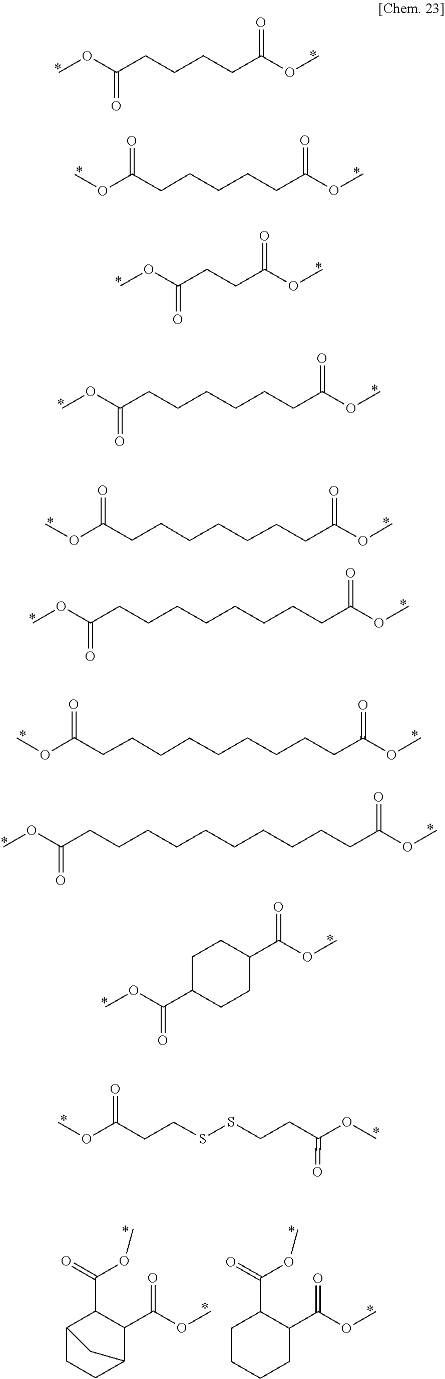

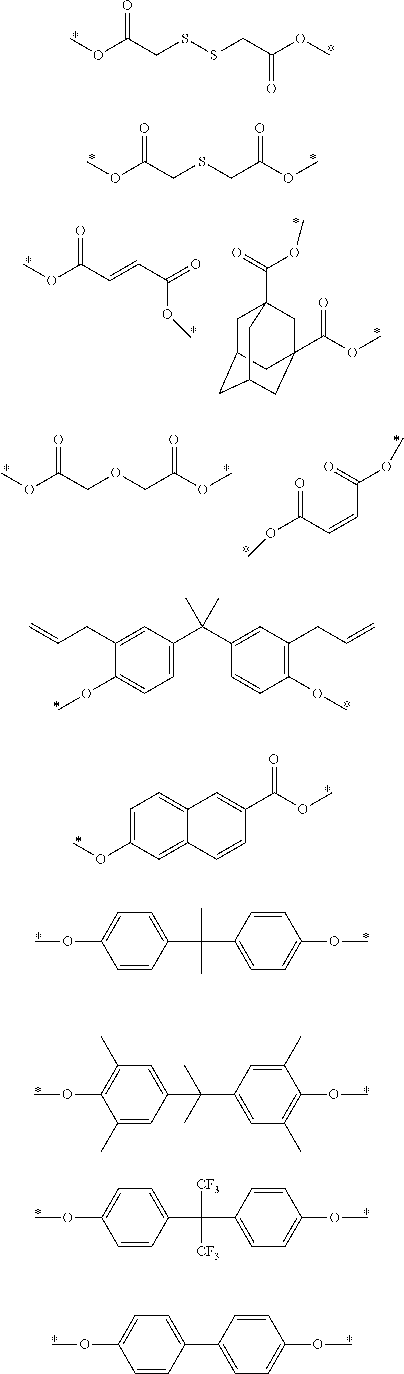

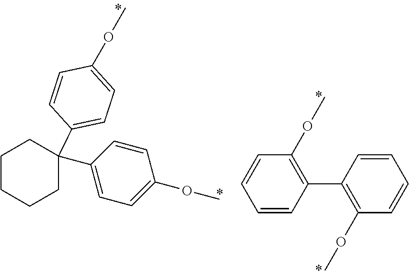

In Formula, * represents a bond.

From the viewpoint of suitably obtaining the effect of the present invention, the polymer (A) preferably has at least one of a repeating unit represented by the following Formula (A) and a repeating unit represented by the following Formula (B).

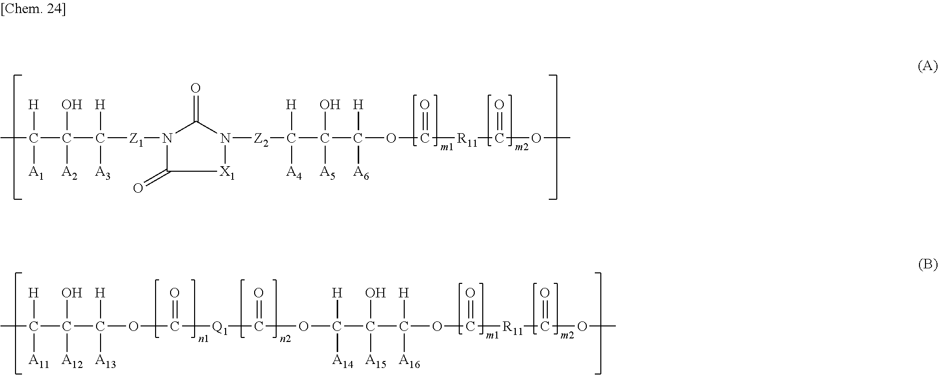

wherein in Formula (A), X₁, Z₁, Z₂, A₁, A₂, A₃, A₄, A₅, and A₆ are the same as X₁, Z₁, Z₂, A₁, A₂, A₃, A₄, A₅, and A₆ in Formula (1), respectively, R₁₁, m1, and m2 are the same as R₁₁, m1, and m2 in Formula (3), respectively,
in Formula (B), Q₁, A₁₁, A₁₂, A₁₃, A₁₄, A₁₅, A₁₆, n1, and n2 are the same as Q₁, A₁, A₁₂, A₁₃, A₁₄, A₁₅, A₁₅, n1, and n2 in Formula (2), respectively, and R₁₁, m1, and m2 are the same as R₁₁, m1, and m2 in Formula (3), respectively.

The molar ratio (M1:M2) between the partial structure (M1) represented by Formula (1) and the partial structure (M2) represented by Formula (2) in the polymer (A) is not particularly limited, but is preferably 95:5 to 10:90, more preferably 95:5 to 20:80, and particularly preferably 95:5 to 40:60.

The molar ratio [(M1+M2):M3] of the sum of the partial structure (M1) represented by Formula (1) and the partial structure (M2) represented by Formula (2) to the partial structure represented by Formula (3) in the polymer (A) is not particularly limited, but is preferably 80:20 to 20:80, more preferably 70:30 to 30:70, and particularly preferably 60:40 to 40; 60.

The molar ratio (MA:MB) between the repeating unit (MA) represented by Formula (A) and the repeating unit (MB) represented by Formula (B) in the polymer (A) is not particularly limited, but is preferably 95:5 to 10:90, more preferably 95:5 to 20:80, and particularly preferably 95:5 to 40:60.

The molar ratio of the sum of the repeating unit (MA) represented by Formula (A) and the repeating unit (MB) represented by Formula (B) to all the repeating units of the polymer (A) is not particularly limited, but is preferably 70 mols or more, more preferably 80 mol % or more, and particularly preferably 90 mol % or more. The upper limit is not particularly limited, but is preferably 100 mol % or less.

Examples of the polymer (A) include the following polymers (1a) to (1n).

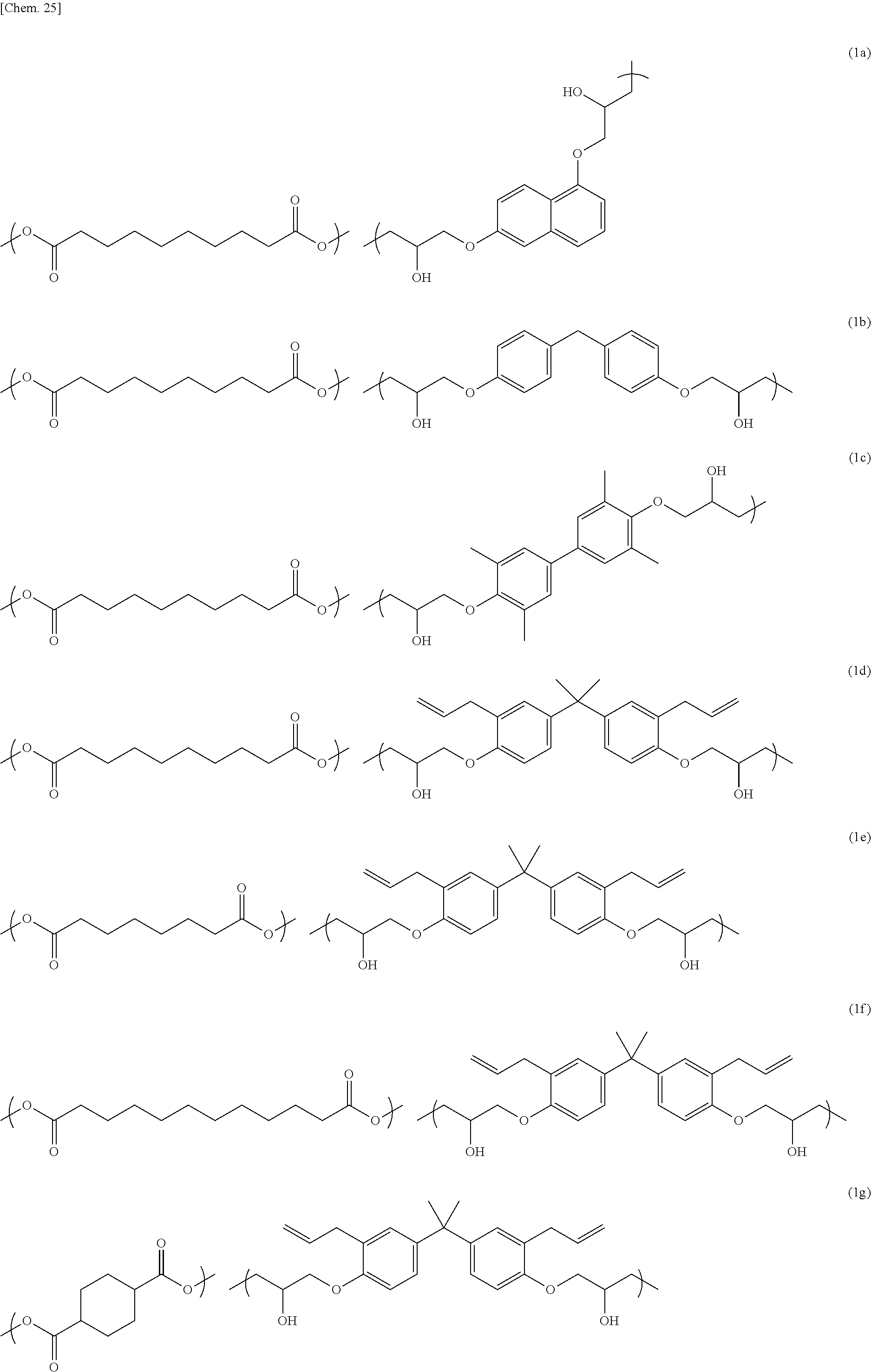

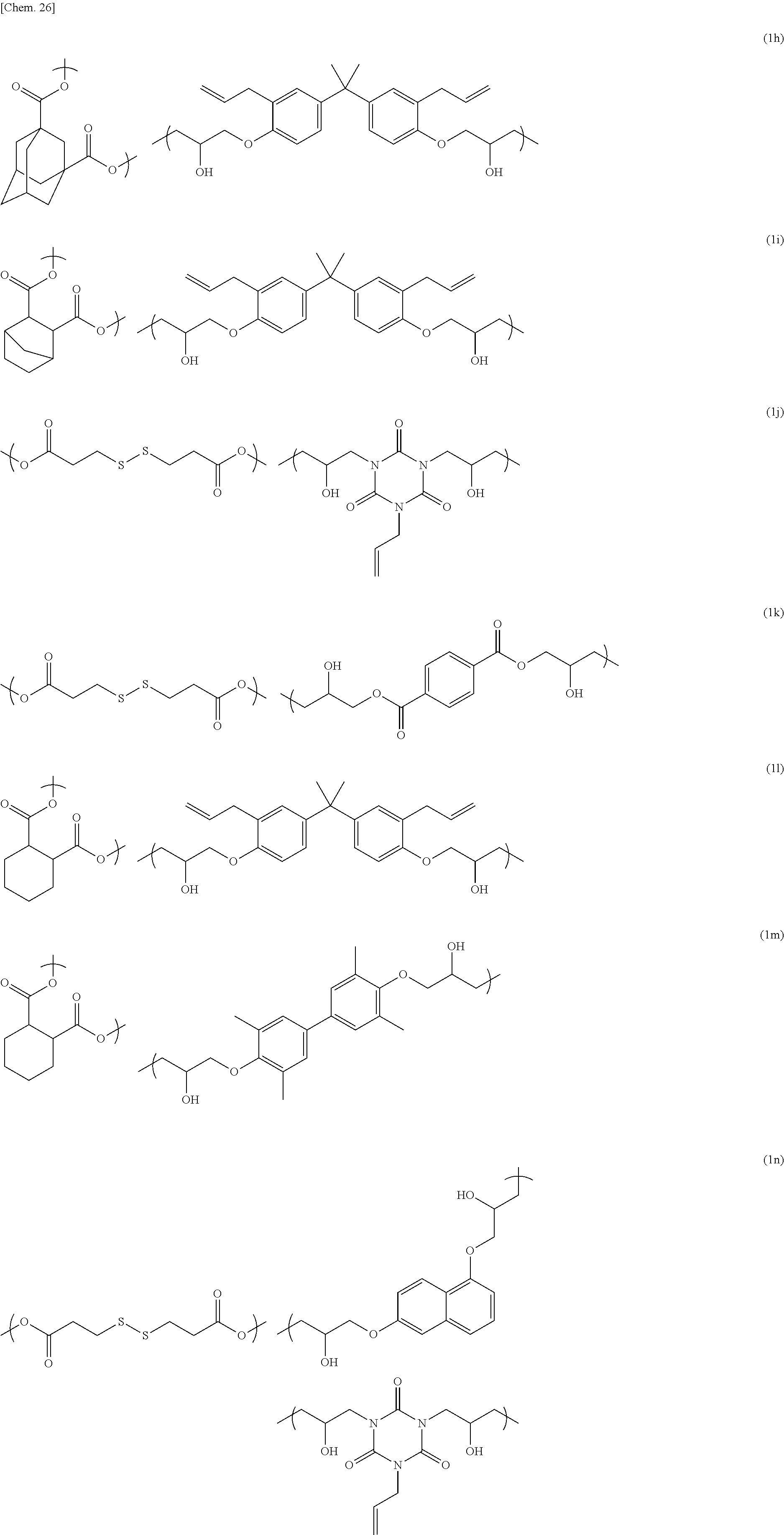

### <<Method for Manufacturing Polymer>>

An example of the method for manufacturing the polymer (A) is not particularly limited, and examples thereof include a method of reacting at least one of a diepoxy compound represented by the following Formula (A1) and a diepoxy compound represented by the following Formula (A2), and a dicarboxylic acid represented by the following Formula (A3).

For example, at least one of a diepoxy compound represented by the following Formula (A1) and a diepoxy compound represented by the following Formula (A2), and a dicarboxylic acid represented by the following Formula (A3) are dissolved in an organic solvent at an appropriate molar ratio. A polymer is obtained by polymerization in the presence of a catalyst that activates an epoxy group.

When the polymer (A) is manufactured, a diepoxy compound other than the diepoxy compound represented by Formula (A1) and the diepoxy compound represented by Formula (A2) may be used in combination. When the polymer is manufactured, a dicarboxylic acid other than the dicarboxylic acid represented by Formula (A3) may be used in combination.

Examples of the catalyst for activating an epoxy group include a quaternary phosphonium salt such as tetrabutylphosphonium bromide or ethyltriphenylphosphonium bromide, and a quaternary ammonium salt such as benzyltriethylammonium chloride. As the amount of the catalyst used, an appropriate amount can be selected and used from the range of 0.1 to 10 mass % with respect to the total mass of the polymer raw material used in the reaction. As the temperature and the time for the polymerization reaction, for example, optimum conditions can be selected from the ranges of 80 to 160° C. and 2 to 50 hours.

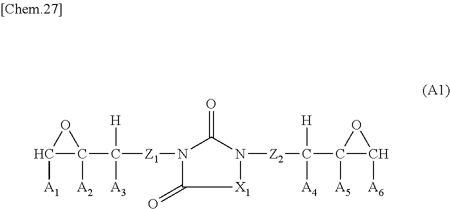

wherein in Formula (A1), X₁, Z₁, Z₂, A₁, A₂, A₃, A₄, A₅, and A₆ are the same as X₁, Z¹, Z₂, A₁, A₂, A₃, A₄, A₅, and A₆ in Formula (1), respectively.

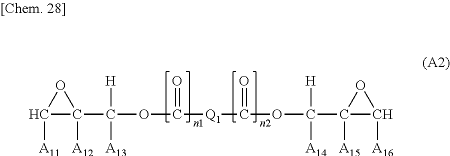

wherein in Formula (A₂), Q₁, A₁₁, A₁₂, A₁₃, A₁₄, A₁₅, A₁₆, n1, and n2 are the same as Q₁, A₁₁, A₁₂, A₁₃, A₁₄, A₁₅, A₁₆, n1, and n2 in Formula (2), respectively.

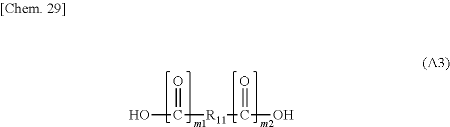

wherein in Formula (A3), R₁₁, m1, and m2 are the same as R₁₁, m1, and m2 in Formula (3), respectively.

Examples of the diepoxy compound represented by Formula (A1) include the following diepoxy compounds,

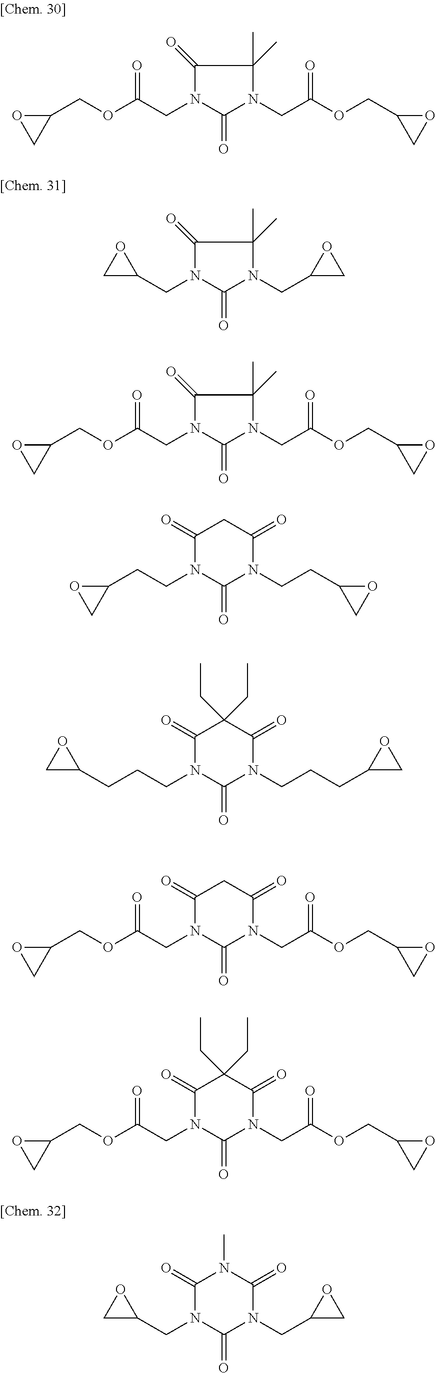

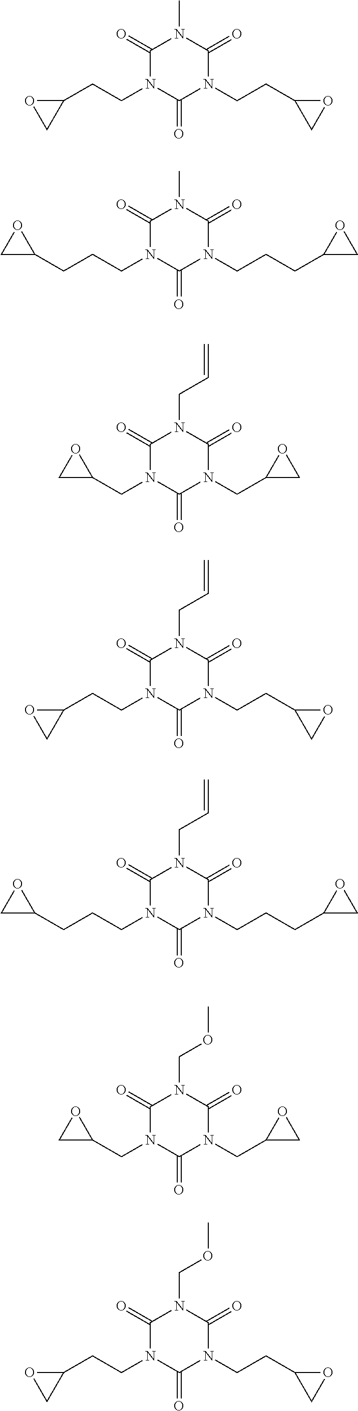

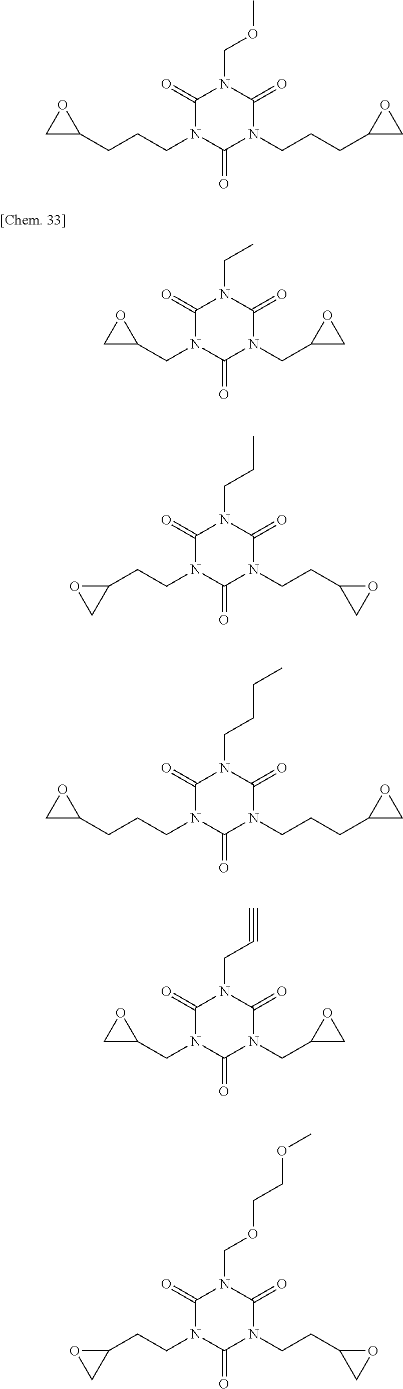 [SMILES: COCn1c(=O)n(CCCC2CO2)c(=O)n(CCCC2CO2)c1=O ; CCn1c(=O)n(CC2CO2)c(=O)n(CC2CO2)c1=O ; CCCn1c(=O)n(CCC2CO2)c(=O)n(CCC2CO2)c1=O ; CCCCn1c(=O)n(CCCC2CO2)c(=O)n(CCCC2CO2)c1=O ; C#CCn1c(=O)n(CC2CO2)c(=O)n(CC2CO2)c1=O ; COCCOCn1c(=O)n(CCC2CO2)c(=O)n(CCC2CO2)c1=O]

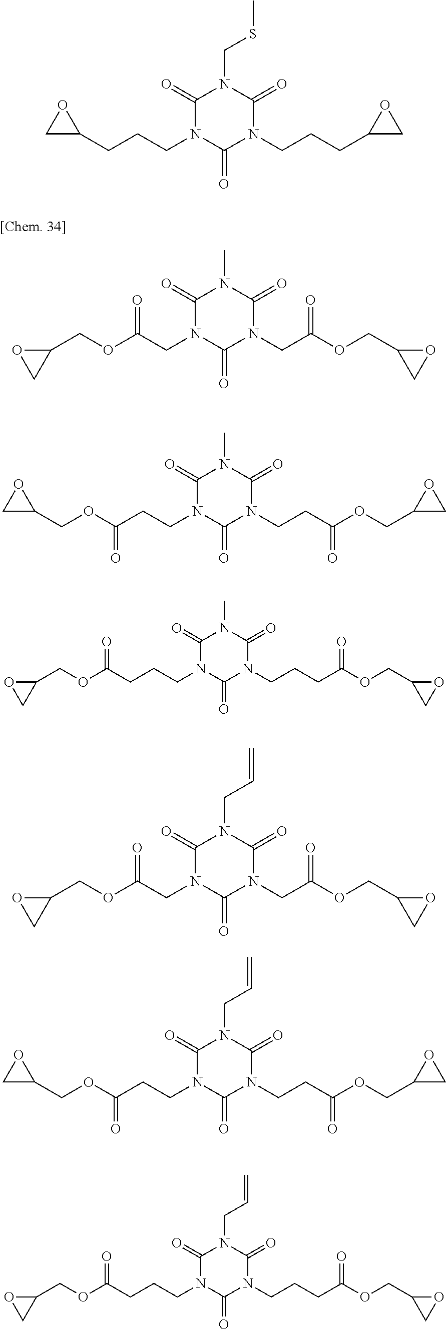

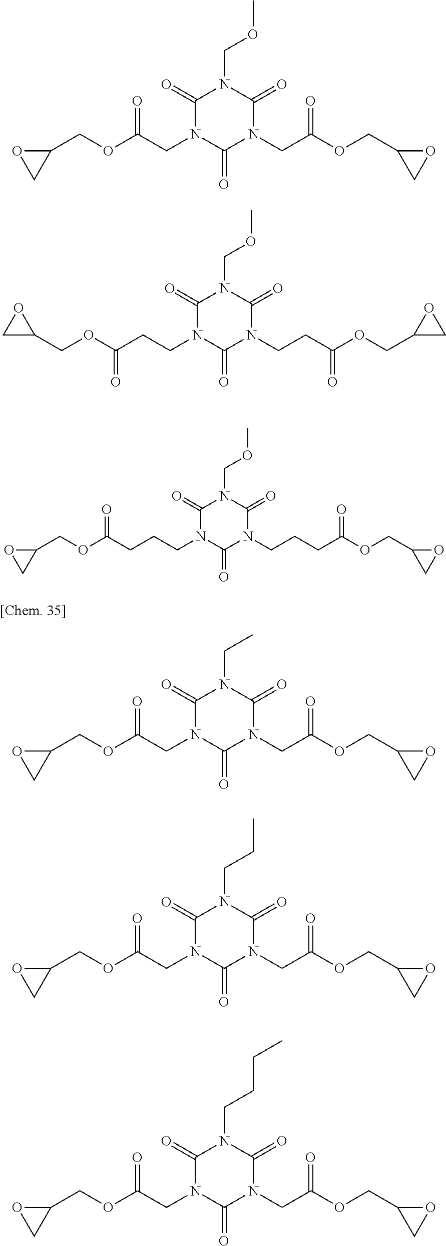

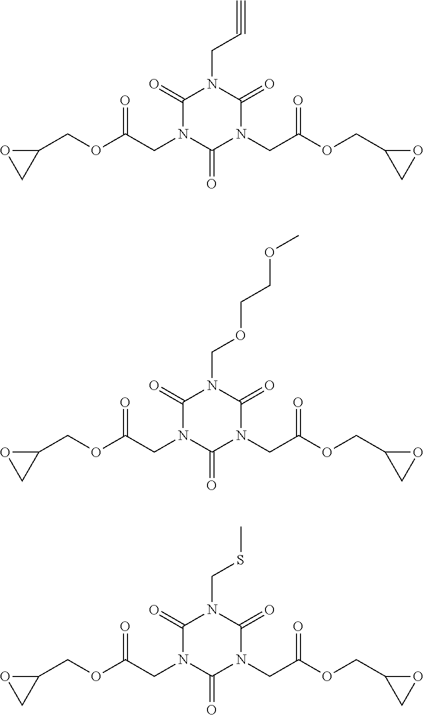 [SMILES: C#CCn1c(=O)n(CC(=O)OCC2CO2)c(=O)n(CC(=O)OCC2CO2)c1=O ; COCCOCn1c(=O)n(CC(=O)OCC2CO2)c(=O)n(CC(=O)OCC2CO2)c1=O ; CSCn1c(=O)n(CC(=O)OCC2CO2)c(=O)n(CC(=O)OCC2CO2)c1=O]

Examples of the diepoxy compound represented by Formula (A2) include the following diepoxy compounds,

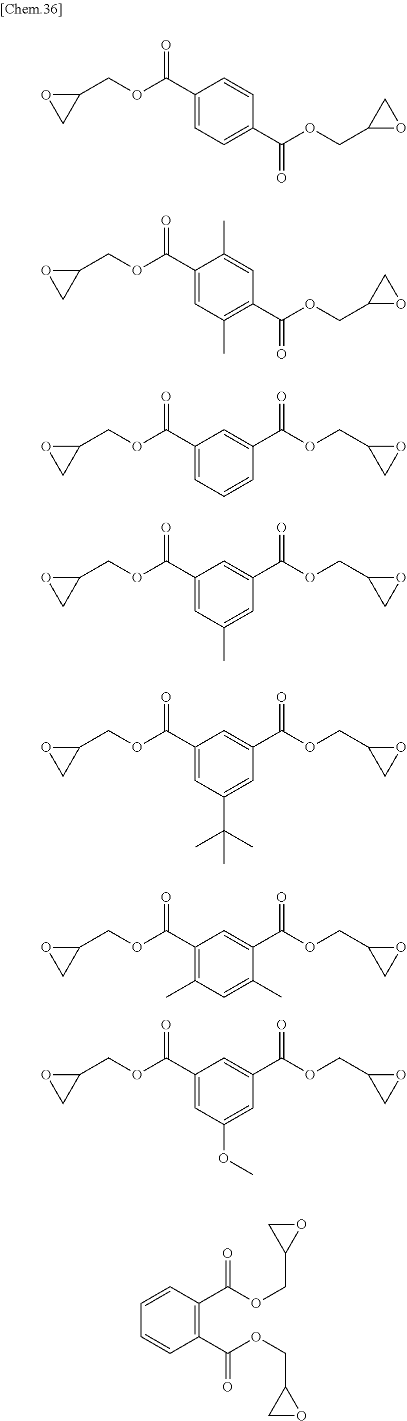

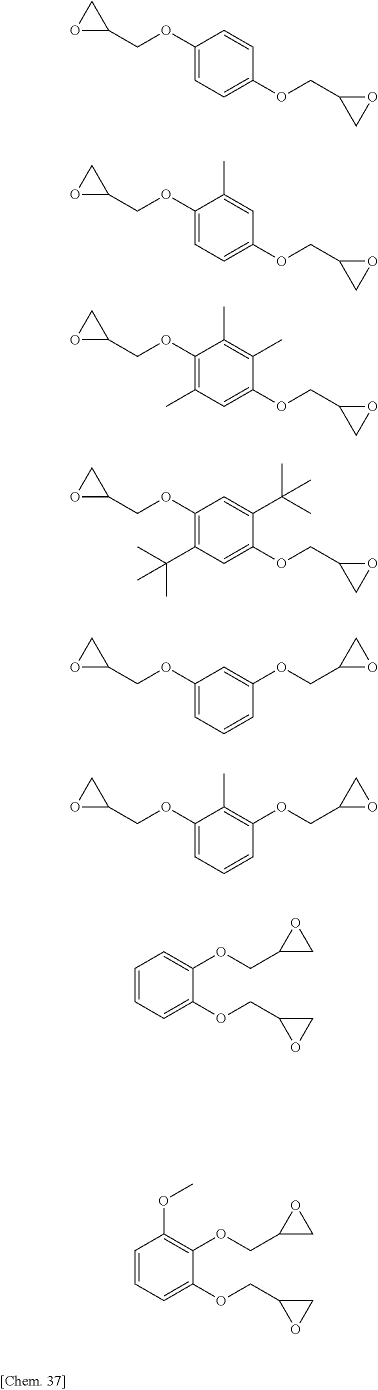

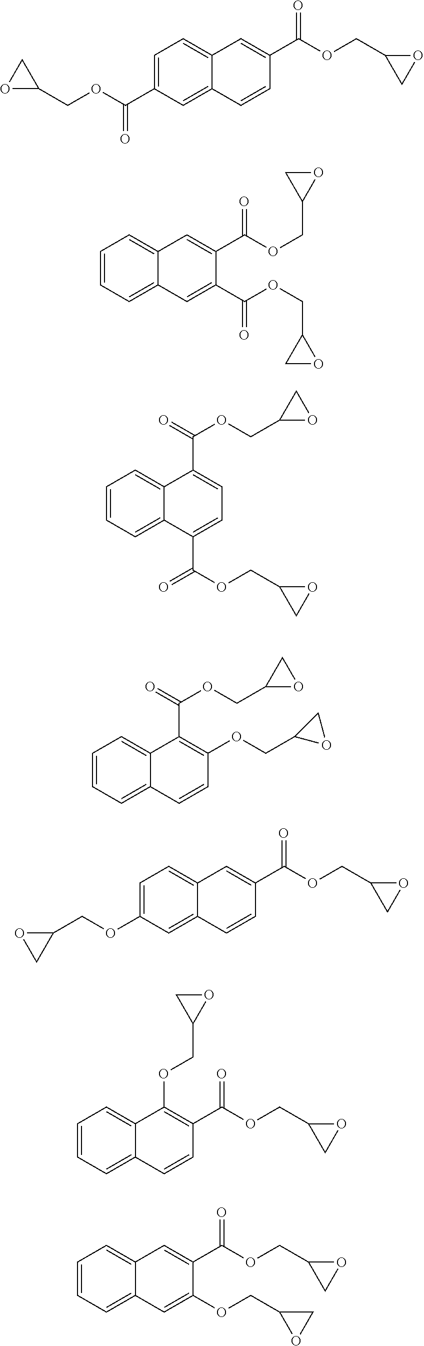

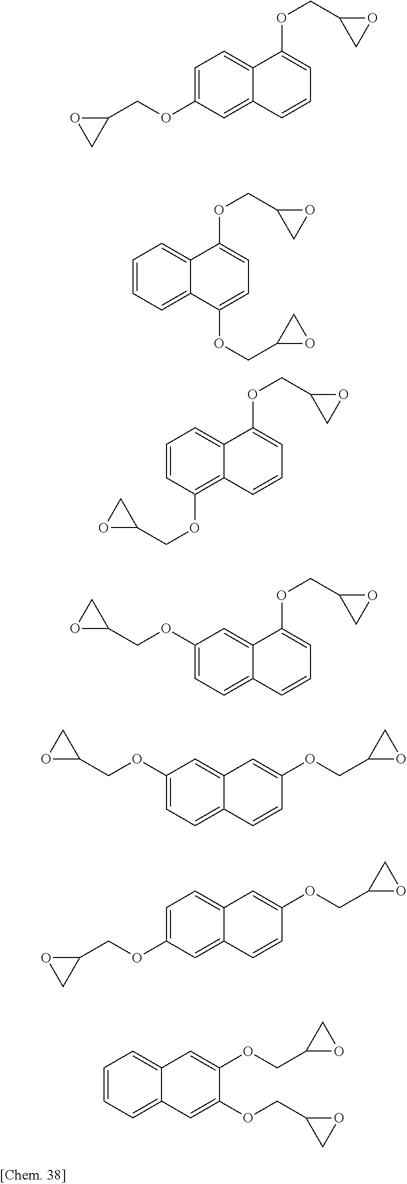

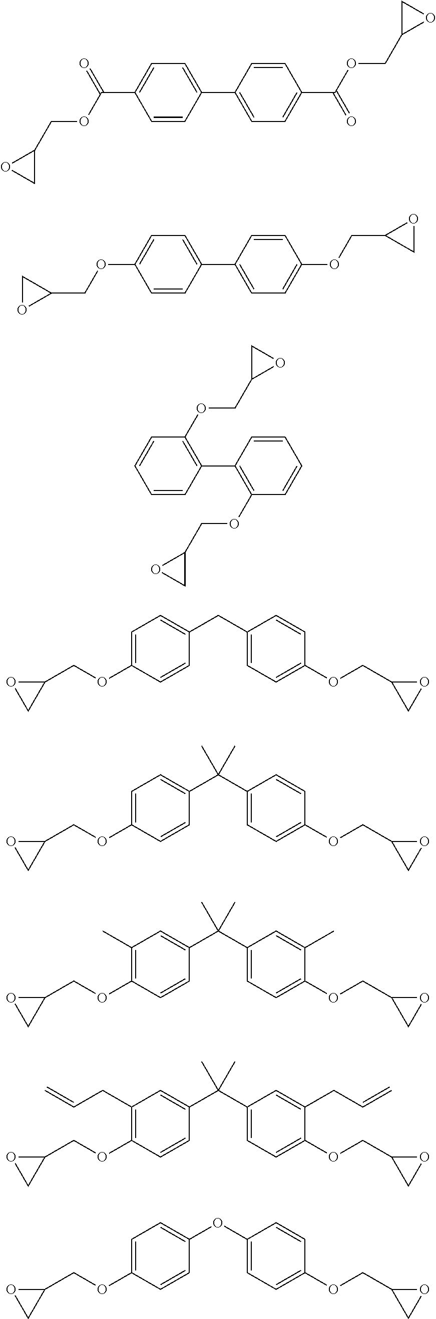

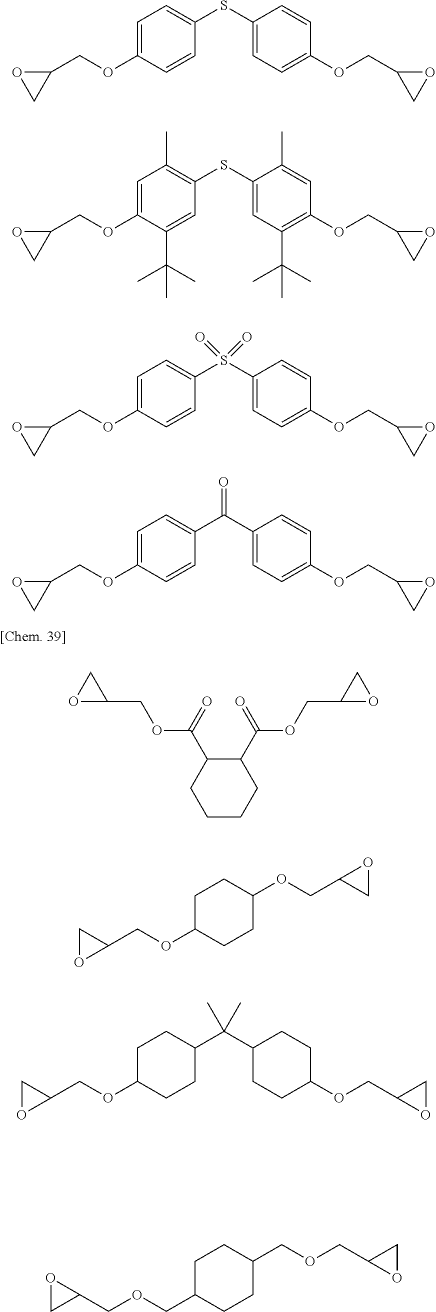

Examples of the dicarboxylic acid represented by Formula (A3) include the following compounds,

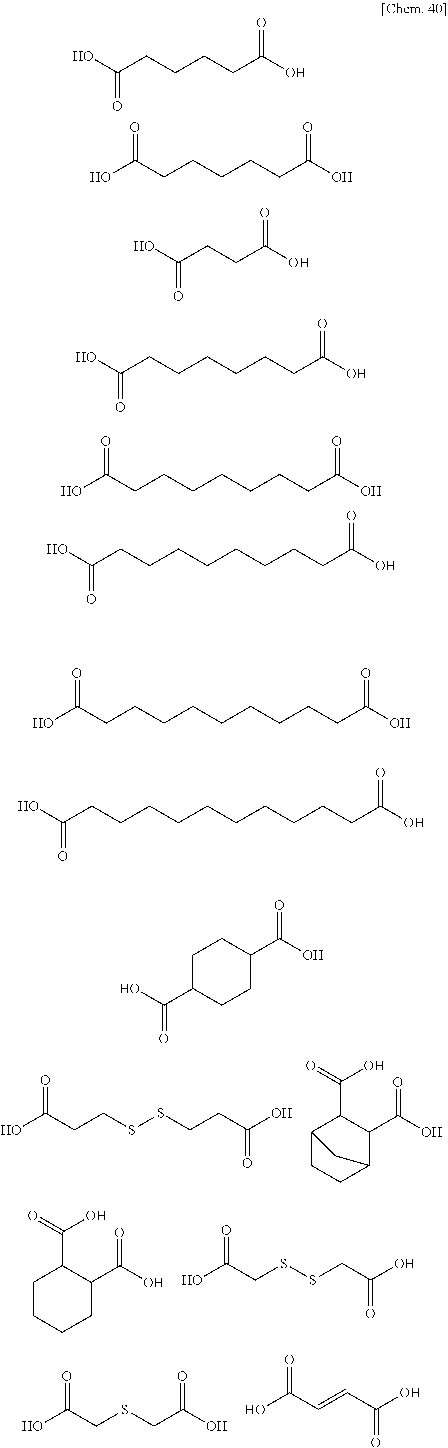

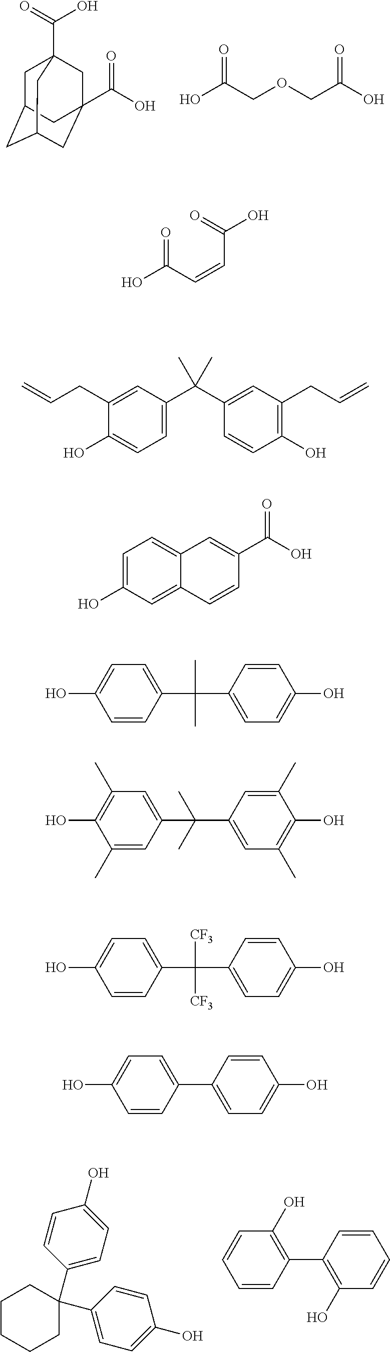

The weight average molecular weight Mw of the polymer (for example, the polymer (A)) is not particularly limited, but is preferably 1,000 to 50,000, more preferably 1,500 to 30,000, and particularly preferably 2,000 to 10,000.

In the present invention, the weight average molecular weight Mw is a value in terms of polystyrene measured by gel permeation chromatography (GPC).

The content of the polymer (for example, the polymer (A)) in the protective film-forming composition is not particularly limited, and is preferably 50 mass % to 100 mass %, more preferably 75 mass& to 100 mass %, and particularly preferably 90 mass % to 100 mass& based on the film-forming component.

### <Component (B)>

The component (B) is a compound having an aromatic ring to which an acyloxy group is directly bonded.

The component (B) may have one aromatic ring to which an acyloxy group is directly bonded, or may have two or more aromatic rings.

The number of aromatic rings to which an acyloxy group is directly bonded included in the component (B) is, for example, 1 to 4.

The aromatic ring in the aromatic ring to which the acyloxy group is directly bonded may be an aromatic hydrocarbon ring or may be an aromatic heterocyclic ring; however, the aromatic ring is preferably an aromatic hydrocarbon ring. Examples of the aromatic hydrocarbon ring include a benzene ring, a naphthalene ring, an anthracene ring, and the like.

The acyloxy group is not particularly limited, but the acyloxy group preferably has 2 to 4 carbon atoms from the viewpoint of suitably obtaining the effect of the present invention. In other words, the acyloxy group is preferably a R^{x}C(═O)O— group (R^{x} represents an alkyl group having 1 to 3 carbon atoms.).

The component (B) is preferably a compound having an aromatic ring in which two or more acyloxy groups are directly bonded from the viewpoint of suitably obtaining the effect of the present invention.

The component (B) is preferably a compound having two or more aromatic rings in which two or more acyloxy groups are directly bonded from the viewpoint of suitably obtaining the effect of the present invention.

Two acyloxy groups in an aromatic ring in which two or more acyloxy groups are directly bonded are preferably adjacently and directly bonded to the aromatic ring Here, being adjacently and directly bonded to an aromatic ring means that two acyloxy groups are directly bonded to the aromatic ring at ortho positions (o-positions).

From the viewpoint of suitably obtaining the effect of the present invention, the component (B) is preferably a compound represented by the following Formula (X-1) or (X-2):

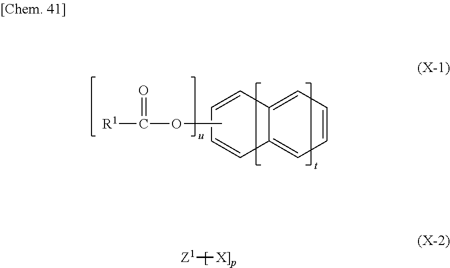

wherein in Formula (X-1), R¹ represents an alkyl group having 1 to 3 carbon atoms, t represents 0 or 1, u represents an integer of 1 to 4, and when there are two or more R¹'s, the two or more R¹'s may be the same or different,
in Formula (X-2), Z¹ represents a p-valent group, p represents an integer of 2 to 4, X's each independently represent an organic group represented by the following Formula (X-2-1).

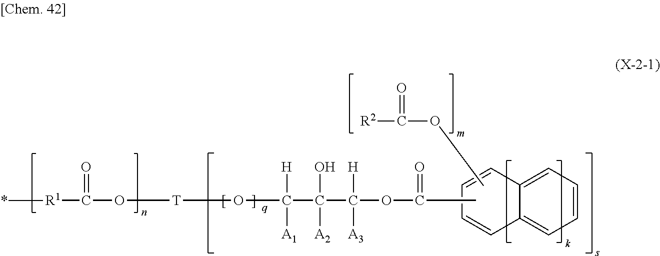

wherein in Formula (X-2-1), R¹ represents a single bond or an alkylene group having 1 to 4 carbon atoms,
R² represents an alkyl group having 1 to 3 carbon atoms,
T represents a single bond or an (s+1)-valent hydrocarbon group having 1 to 8 carbon atoms,
A₁ to A₅ each independently represent a hydrogen atom, a methyl group, or an ethyl group,
k represents 0 or 1,
m represents an integer of 1 to 4,
n represents 0 or 1,
q represents 0 or 1,
s represents 1 or 2,
when there are two or more R²'s, the two or more R²'s may be the same or different,
* represents a bonding moiety to Z¹ in Formula (X-2), provided that when T is a single bond, n and q are not simultaneously 1.

Z¹ in Formula (X-2) is preferably represented by the following Formulae (X-2-2) to (X-2-6).

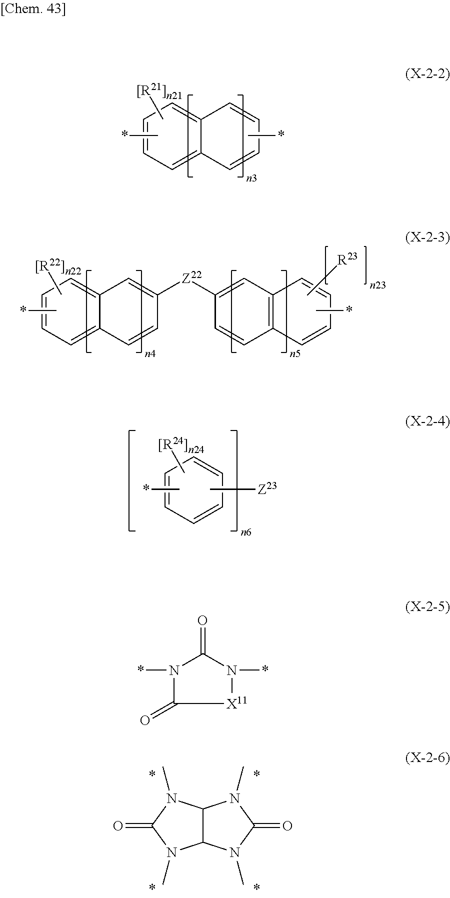

wherein in Formulae (X-2-2) to (X-2-4), R²¹ to R²⁴ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms,
in Formula (X-2-2), n3 represents 0 or 1, when n3 is 0, n21 represents an integer of 0 to 4, when n3 is 1, n21 represents an integer of 0 to 6, and when there are two or more R²¹'s, the two or more R²¹'s may be the same or different,
in Formula (X-2-3), Z²² represents a single bond, an oxygen atom, a sulfur atom, a carbonyl group, a sulfonyl group, or an alkylene group having 1 to 6 carbon atoms, n4 and n5 each independently represent 0 or 1, when n4 is 0, n22 represents an integer of 0 to 4, when n4 is 1, n22 represents an integer of 0 to 6, when there are two or more R²²'s, the two or more R²²'s may be the same or different, when n5 is 0, n23 represents an integer of 0 to 4, when n5 is 1, n23 represents an integer of 0 to 6, and when there are two or more R²³'s, the two or more R²³'s may be the same or different,
in Formula (X-2-4), n6 represents 3 or 4, Z²³ represents a no-valent group, n24's each independently represent an integer of 0 to 4, a plurality of R²⁴'s may be the same or different,
in Formula (X-2-5), X¹¹ represents a group represented by the following Formula (X-2-5-1), the following Formula (X-2-5-2), the following Formula (X-2-5-3), or the following Formula (X-2-5-4), and
* represents a bond to X in Formula (X-2),

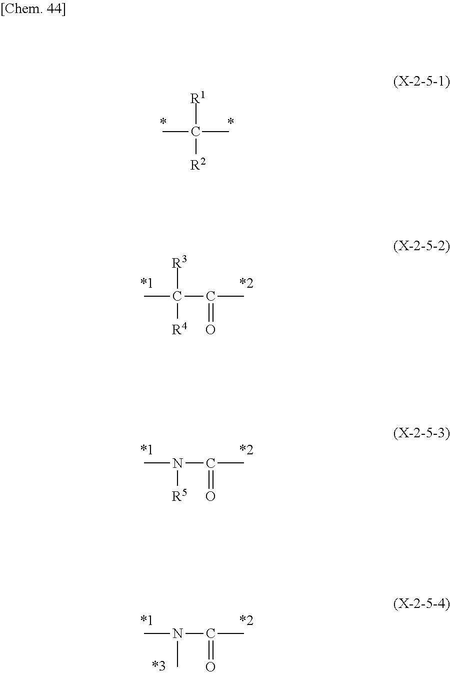

wherein in Formulae (X-2-5-1) to (X-2-5-4),
R¹ to R⁵ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent functional group selected from the group consisting of an alkyl group having 1 to 6 carbon atoms, a halogen atom, an alkoxy group having 1 to 10 carbon atoms, a nitro group, a cyano group, and an alkylthio group having 1 to 6 carbon atoms,
* represents a bond, *1 represents a bond bonded to a carbon atom in Formula (X-2-5), *2 represents a bond bonded to a nitrogen atom in Formula (X-2-5), and *3 represents a bond to X in Formula (X-2).

Z²³ in Formula (X-2-4) is not particularly limited as long as it is a trivalent or tetravalent group, and examples thereof include an organic group having 1 to 20 carbon atoms. Examples of the organic group having 1 to 20 carbon atoms include a hydrocarbon group having 1 to 20 carbon atoms.

Z²³ may have a heteroatom or may not have a heteroatom. Examples of the heteroatom include an oxygen atom, a nitrogen atom, and a sulfur atom.

Z²³ may have an aromatic ring or may not have an aromatic ring. Examples of the aromatic ring include an aromatic hydrocarbon ring and an aromatic heterocyclic ring. Examples of the aromatic hydrocarbon ring include a benzene ring, a naphthalene ring, an anthracene ring, and the like.

Examples of the compound represented by Formula (X-1) include the following compounds.

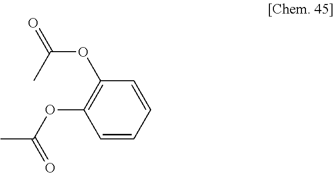

Examples of the compound represented by Formula (X-2) include the following compounds.

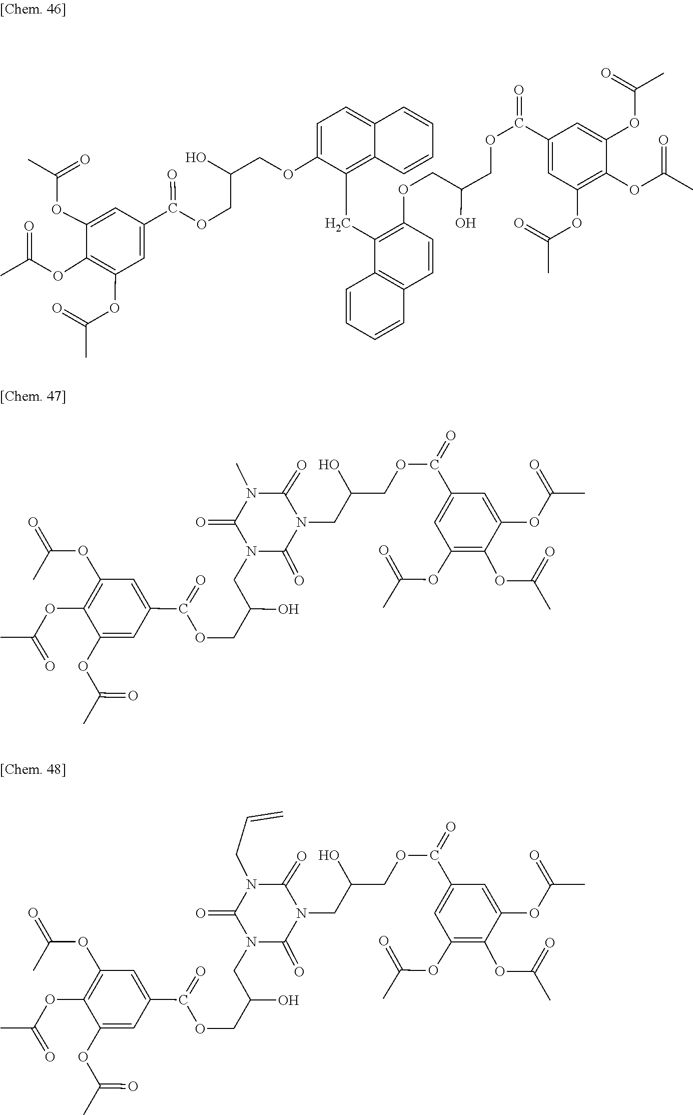

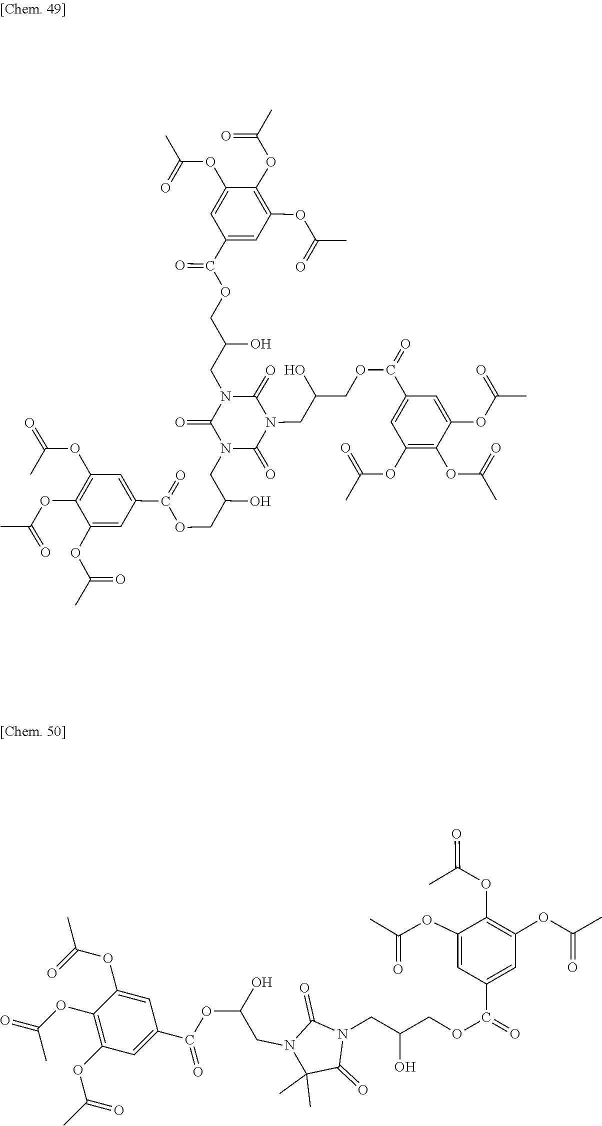 [SMILES: CC(=O)Oc1cc(C(=O)OCC(O)Cn2c(=O)n(CC(O)COC(=O)c3cc(OC(C)=O)c(OC(C)=O)c(OC(C)=O)c3)c(=O)n(CC(O)COC(=O)c3cc(OC(C)=O)c(OC(C)=O)c(OC(C)=O)c3)c2=O)cc(OC(C)=O)c1OC(C)=O ; CC(=O)Oc1cc(C(=O)OCC(O)CN2C(=O)N(CC(O)OC(=O)c3cc(OC(C)=O)c(OC(C)=O)c(OC(C)=O)c3)C(C)(C)C2=O)cc(OC(C)=O)c1OC(C)=O]

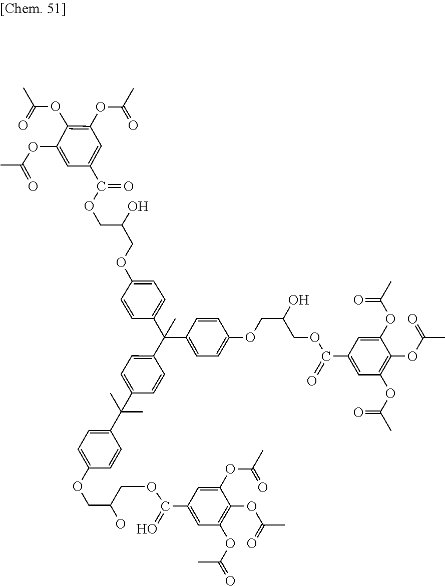 [SMILES: CC(=O)Oc1cc(C(=O)OCC(O)COc2ccc(C(C)(C)c3ccc(C(C)(c4ccc(OCC(O)COC(=O)c5cc(OC(C)=O)c(OC(C)=O)c(OC(C)=O)c5)cc4)c4ccc(OCC(O)COC(=O)c5cc(OC(C)=O)c(OC(C)=O)c(OC(C)=O)c5)cc4)cc3)cc2)cc(OC(C)=O)c1OC(C)=O]

The compound represented by Formula (X-2) is obtained by, for example, reacting a compound represented by the following Formula (X-2A) with a compound represented by the following Formula (X-2B).

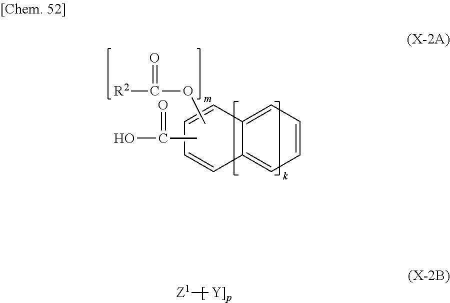

wherein in Formula (X-2A), R² represents an alkyl group having 1 to 3 carbon atoms, k represents 0 or 1, m represents an integer of 1 to 4, and when there are two or more R¹'s, the two or more R¹'s may be the same or different,
in Formula (X-2B), Z¹ represents a p-valent group, P represents an integer of 2 to 4, and Y's each independently represent an organic group represented by the following Formula (X-2-1B).

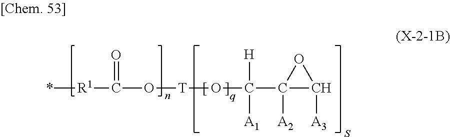

wherein in Formula (X-2-1B), R¹ represents a single bond or an alkylene group having 1 to 4 carbon atoms,
T represents a single bond or an (s+1)-valent hydrocarbon group having 1 to 8 carbon atoms,
A₁ to A₃ each independently represent a hydrogen atom, a methyl group, or an ethyl group,
n represents 0 or 1,
q represents 0 or 1,
s represents 1 or 2,
when there are two or more R¹'s, the two or more R¹'s may be the same or different,
* represents a bonding moiety to Z¹ in Formula (X-2B),
provided that when T is a single bond, n and q are not simultaneously 1.

In Formula (X-2B), 21 represents, for example, groups represented by Formula (X-2-2) to Formula (X-2-6).

Examples of the compound represented by Formula (X-2A) include the following compounds.

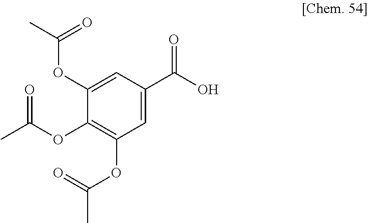 [SMILES: CC(=O)Oc1cc(C(=O)O)cc(OC(C)=O)c1OC(C)=O]

Examples of the compound represented by Formula (X-2B) include the following compounds.

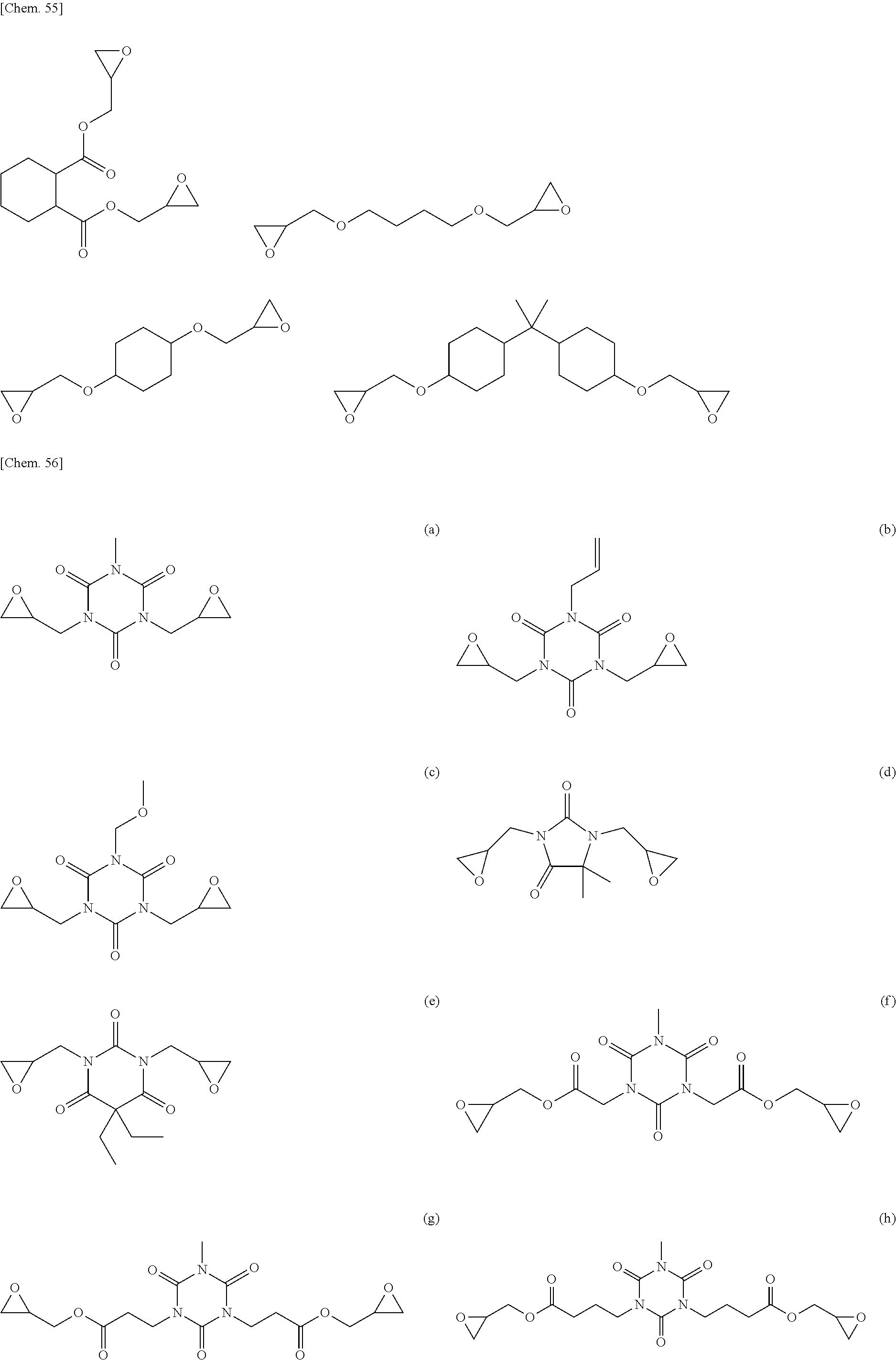

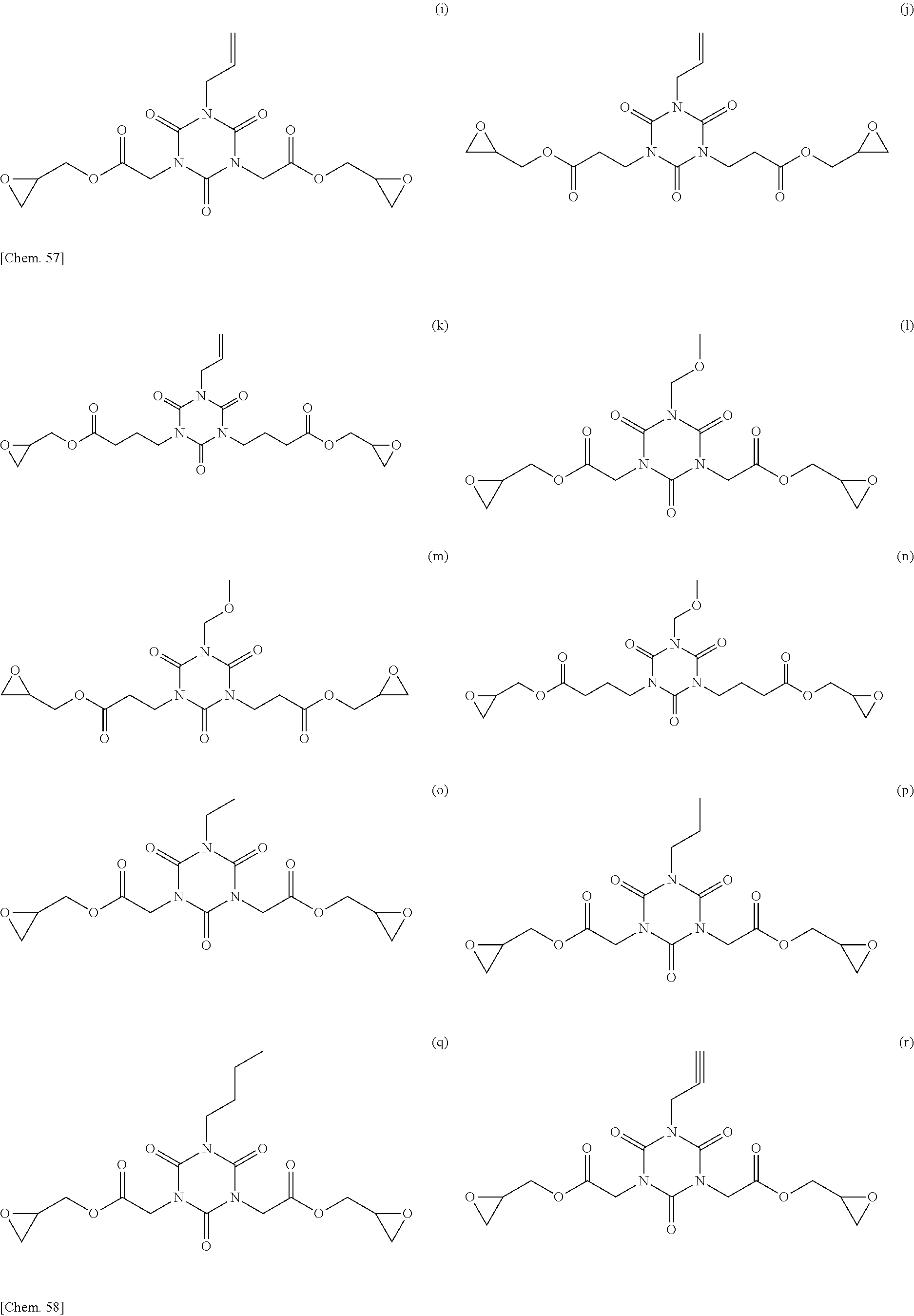

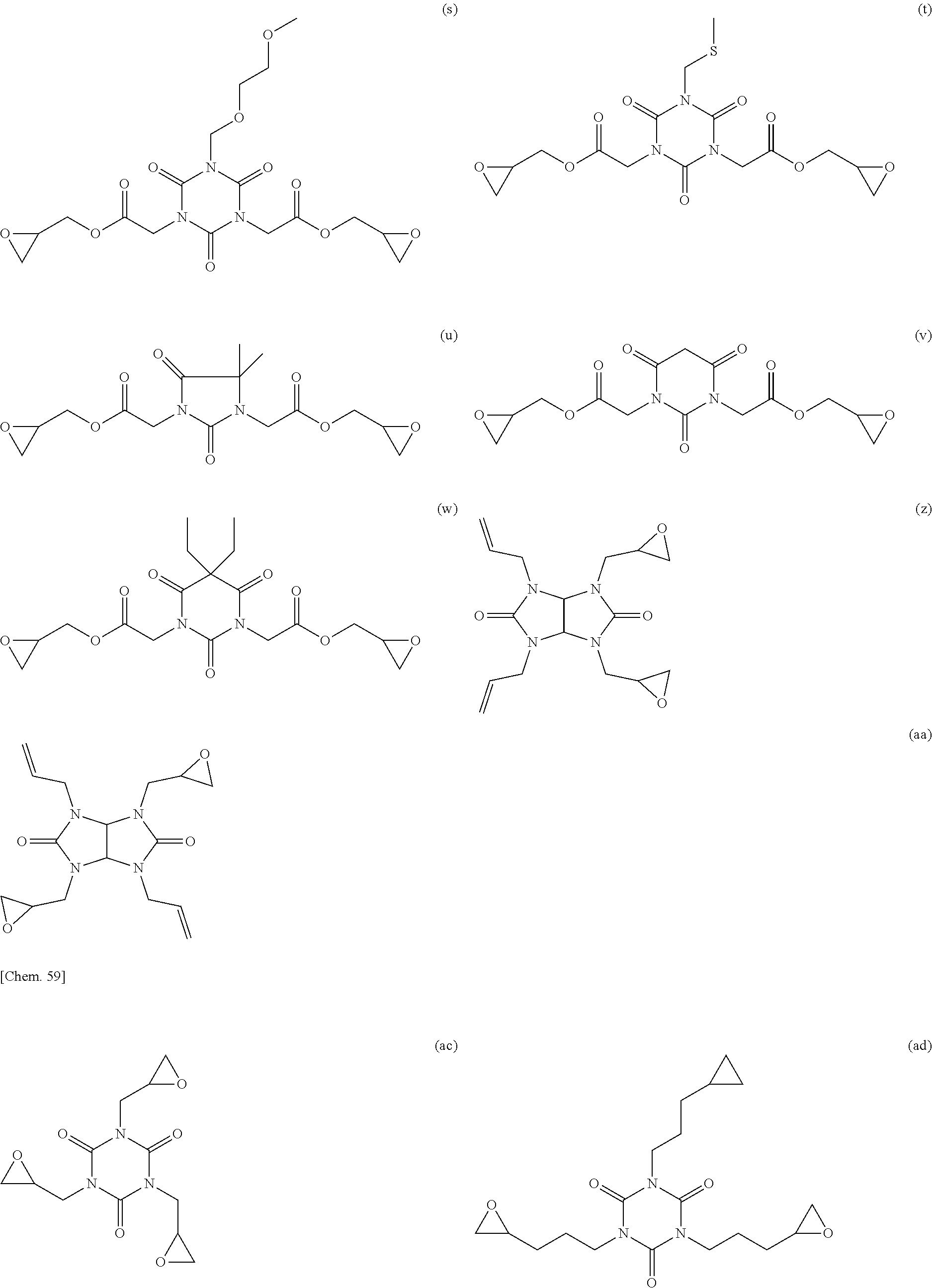

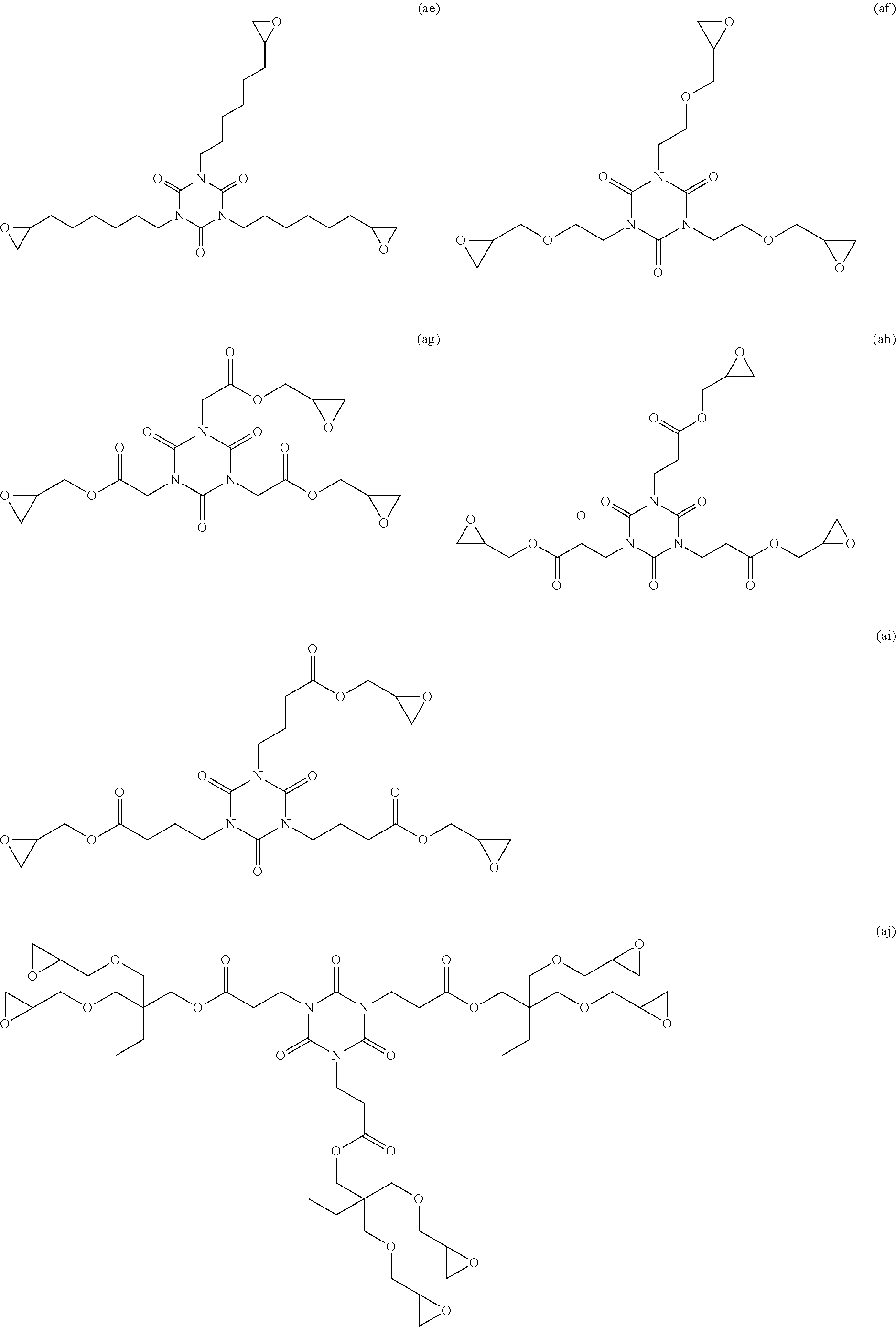

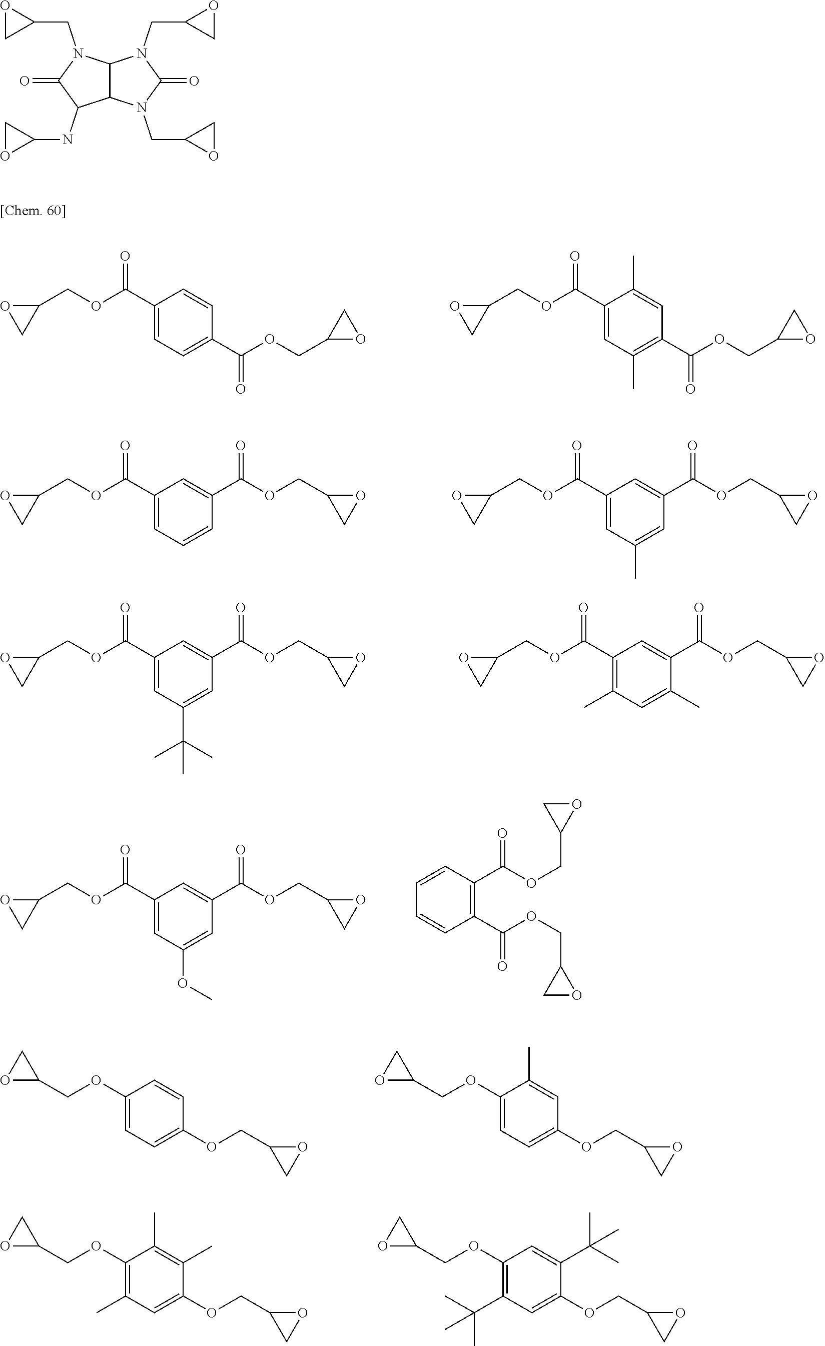

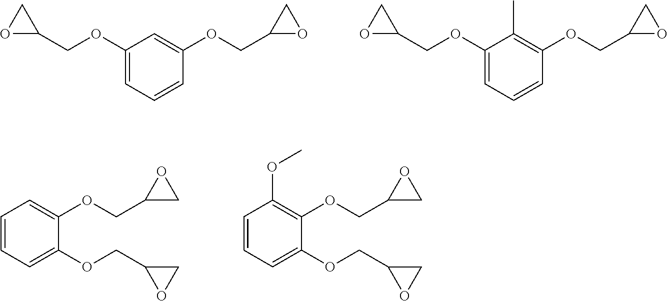 [SMILES: c1cc(OCC2CO2)cc(OCC2CO2)c1 ; Cc1c(OCC2CO2)cccc1OCC1CO1 ; c1ccc(OCC2CO2)c(OCC2CO2)c1 ; COc1cccc(OCC2CO2)c1OCC1CO1]

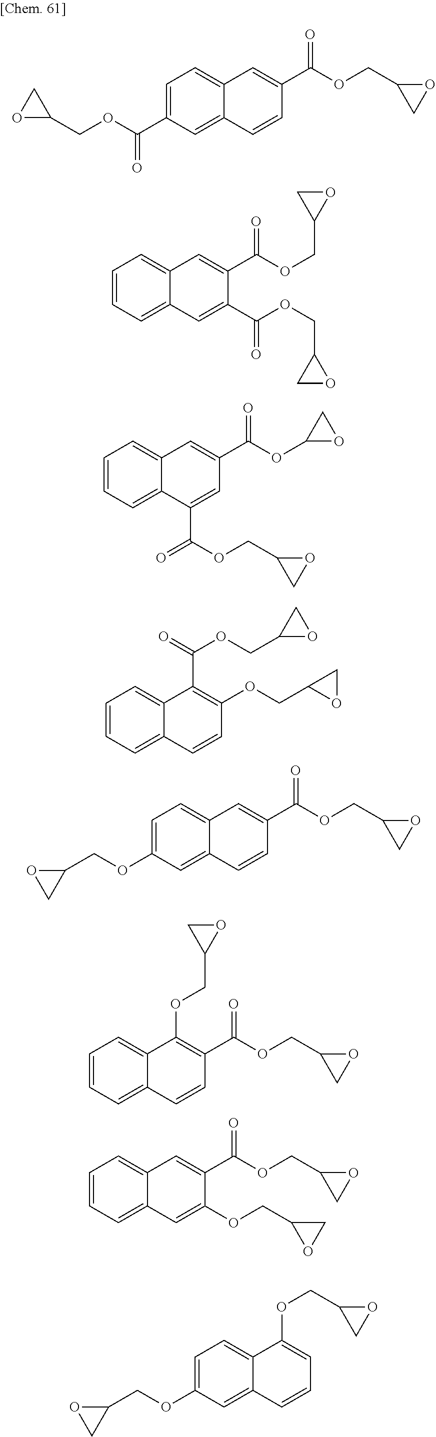

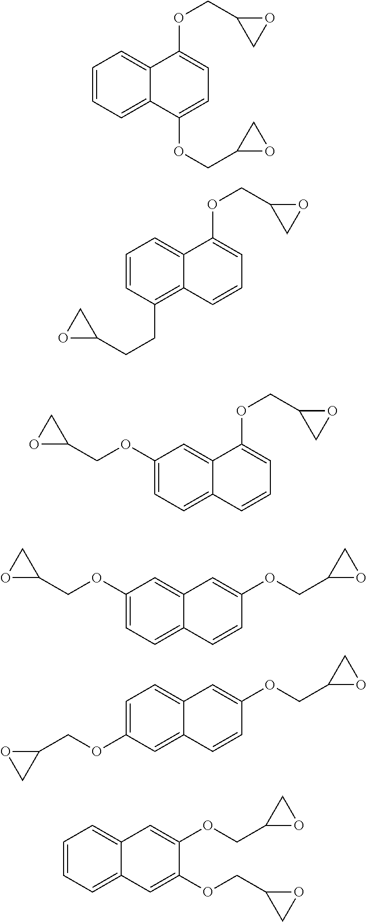

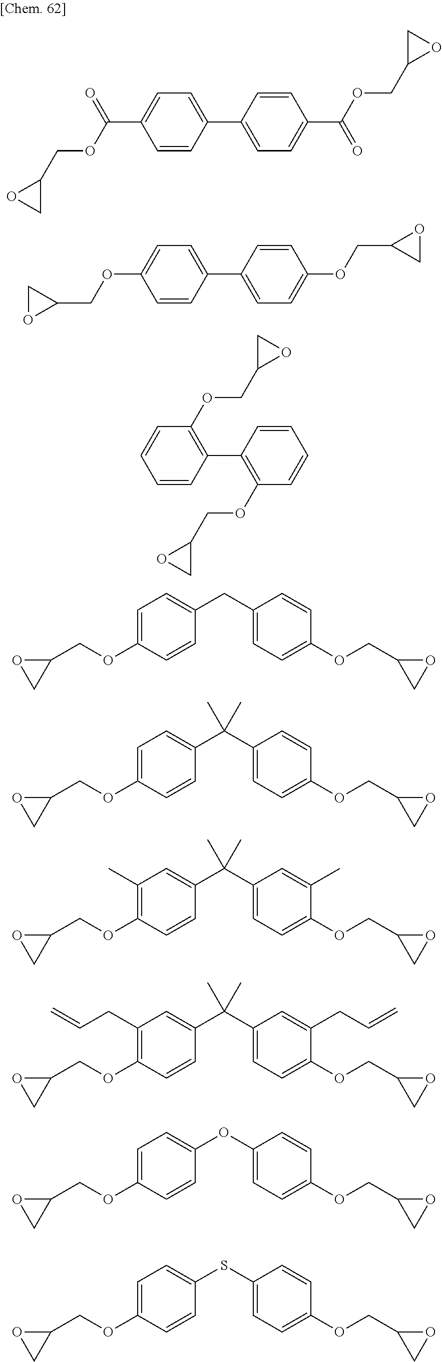

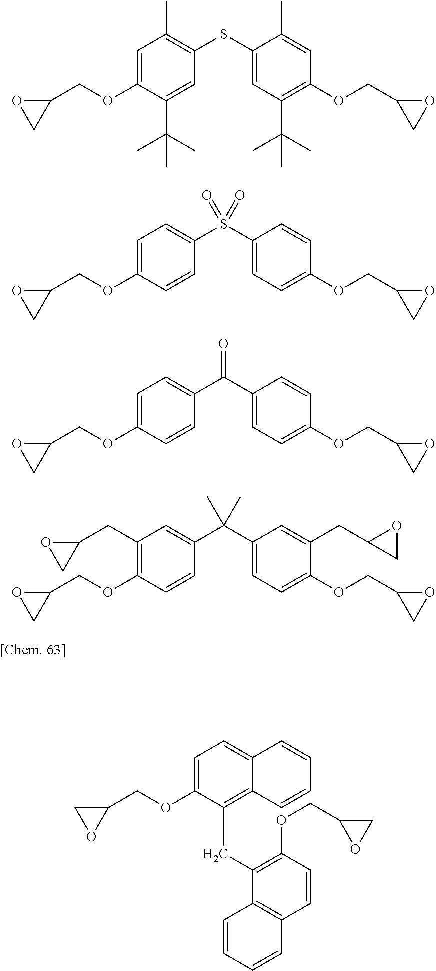

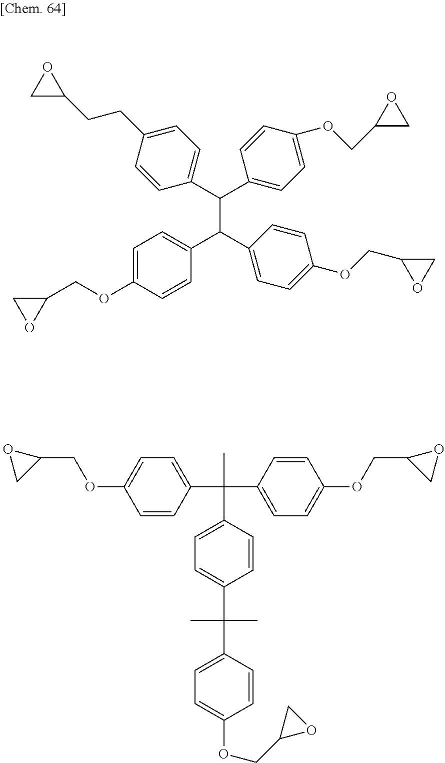 [SMILES: c1cc(C(c2ccc(OCC3CO3)cc2)C(c2ccc(OCC3CO3)cc2)c2ccc(OCC3CO3)cc2)ccc1CCC1CO1 ; CC(C)(c1ccc(OCC2CO2)cc1)c1ccc(C(C)(c2ccc(OCC3CO3)cc2)c2ccc(OCC3CO3)cc2)cc1]

The content of the component (B) in the protective film-forming composition is not particularly limited, and is preferably 0.01 parts by mass to 50 parts by mass, more preferably 0.1 parts by mass to 10 parts by mass and particularly preferably 0.5 parts by mass to 5 parts by mass, with respect to 100 parts by mass of the component (A), from the viewpoint of suitably obtaining the effect of the present invention.

The content of the component (B) in the protective film-forming composition is not particularly limited, and is preferably 0.01 parts by mass to 50 parts by mass, more preferably 0.1 parts by mass to 10 parts by mass and particularly preferably 0.5 parts by mass to 5 parts by mass, with respect to 100 parts by mass of the polymer (for example, the polymer (A)), from the viewpoint of suitably obtaining the effect of the present invention.

### <Curing Catalyst>

As the curing catalyst contained as an optional component in the protective film-forming composition, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include onium salt compounds, sulfonimide compounds, and disulfonyl diazomethane compounds.

Examples of the onium salt compounds include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl) iodonium camphorsulfonate, and bis(4-tert-butylphenyl) iodonium trifluoromethanesulfonate, sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate, and the like.

Examples of the sulfonimide compound include N-(trifluoromethanesulfonyloxy) succinimide, N-(nonafluoro-normal-butanesulfonyloxy) succinimide, N-(camphorsulfonyloxy) succinimide, and N-(trifluoromethanesulfonyloxy) naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, methylsulfonyl-p-toluenesulfonyl diazomethane, and the like.

Only one type of curing catalyst can be used, or two or more types thereof can be used in combination.

In the case of using the curing catalyst, the content ratio of the curing catalyst is, for example, 0.1 mass % to 50 mass %, and preferably 1 mass % to 30 mass % with respect to the component (A).

### <(C) Solvent>

The protective film-forming composition of the present invention can be prepared by dissolving the respective components described above in a solvent, preferably in an organic solvent, and is used in a uniform solution state.

The organic solvent of the protective film-forming composition according to the present invention can be used without particular limitation as long as it is an organic solvent capable of dissolving solid components such as the component (A), the component (B), and other optional solid components. In particular, since the protective film-forming composition according to the present invention is used in a uniform solution state, it is recommended to use an organic solvent generally used in a lithography process in combination in consideration of application performance thereof.

Examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monoethyl ether, propylene glycol monomethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, 2-heptanone, methoxycyclopentane, anisole, γ-butyrolactone, N-methylpyrrolidone, N, N-dimethylformamide, and N, N-dimethylacetamide. One of these solvents can be used alone, or two or more of these solvents can be used in combination.

Among these solvents, propylene glycol monomethyl ether, propylene glycol monomethyl ether acetate, cyclohexanone, and the like are preferable. In particular, propylene glycol monomethyl ether and propylene glycol monomethyl ether acetate are preferable.

A solid content of the protective film-forming composition according to the present invention is usually 0.1 to 70 mass %, and preferably 0.1 to 60 mass %. The solid content is the content ratio of all components excluding the solvent from the protective film-forming composition. The proportion of the component (A) in the solid content is preferably 1 to 99.9 mass %, more preferably 50 to 99.9 mass %, still more preferably 50 to 95 mass %, and particularly preferably 50 to 90 mass %.

(Protective Film, Method for Manufacturing Substrate with Protective Film, Method for Manufacturing Substrate with Resist Pattern, and Method for Manufacturing Semiconductor Device)

A protective film of the present invention is a baked product of a coating film formed of a protective film-forming composition.

The method for manufacturing a substrate with a protective film of the present invention includes a step of applying the protective film-forming composition of the present invention on a stepped semiconductor substrate and baking the protective film-forming composition to form a protective film.

The method for manufacturing a substrate with a resist pattern according to the present invention includes the following steps (1) and (2).
Step (1): a step of applying the protective film-forming composition of the present invention on a semiconductor substrate and baking the protective film-forming composition to form a protective film as a resist underlayer film
Step (2): a step of forming a resist film directly on the protective film or over the protective film, with another layer interposed between the resist film and the protective film, and exposing and developing the resist film to form a resist pattern

A method for manufacturing a semiconductor device according to the present invention includes the following processes (A) to (D).
Process (A): a process of forming a protective film by using the protective film-forming composition of the present invention on a semiconductor substrate having a surface on which an inorganic film is formed
Process (B): a process of forming a resist pattern directly on the protective film or over the protective film, with another layer interposed between the resist pattern and the protective film
Process (C): a process of dry etching the protective film by using the resist pattern as a mask to expose a surface of the inorganic film
Process (D): a process of wet etching the inorganic film by using the protective film after dry etching as a mask with a semiconductor wet etching solution

Examples of the semiconductor substrate onto which the protective film-forming composition (resist underlayer film-forming composition) of the present invention is applied include a silicon wafer, a germanium wafer, and a semiconductor wafer formed of a compound such as gallium arsenide, indium phosphide, gallium nitride, indium nitride, or aluminum nitride.

In the case of using the semiconductor substrate having a surface on which an inorganic film is formed, the inorganic film is formed by, for example, an atomic layer deposition (ALD) method, a chemical vapor deposition (CVD) method, a reactive sputtering method, an ion plating method, a vacuum deposition method, or a spin coating method (spin-on-glass, SOG). Examples of the inorganic film include a polysilicon film, a silicon oxide film, a silicon nitride film, a silicon oxynitride film, a boro-phospho silicate glass (BPSG) film, a titanium nitride film, a titanium oxynitride film, a tungsten nitride film, a gallium nitride film, and a gallium arsenide film.

The semiconductor substrate may be a stepped substrate in which so-called vias (holes), trenches (grooves), and the like are formed. For example, the via has a substantially circular shape when viewed from an upper surface, a substantially circular diameter of the via is, for example, 2 nm to 20 nm, a depth of the via is 50 nm to 500 nm, a width of the groove (a recess of the substrate) of the trench is, for example, 2 nm to 20 nm, and a depth of the trench is 50 nm to 500 nm. Since the protective film-forming composition (resist underlayer film-forming composition) of the present invention has a small weight-average molecular weight and average particle size of the compound contained in the composition, the composition can be embedded even in the stepped substrate as described above without a defect such as a void. It is an important characteristic that there are no defects such as voids for the next step (wet etching and dry etching of semiconductor substrate, the formation of a resist pattern) of semiconductor manufacturing.

The protective film-forming composition of the present invention is applied onto such a semiconductor substrate by an appropriate application method such as a spinner or a coater, Thereafter, the protective film is formed by baking using heating means such as a hot plate. Baking conditions are appropriately selected from a baking temperature of 100° C. to 400° C. and a baking time of 0.3 minutes to 60 minutes. The baking temperature is preferably 120° C. to 350° C. and the baking time is preferably 0.5 minutes to 30 minutes, and the baking temperature is more preferably 150° C. to 300° C., and the baking time is more preferably 0.8 minutes to 10 minutes. The film thickness of the formed protective film is, for example, 0.001 μm to 10 μm, preferably 0.002 μm to 1 μm, and more preferably 0.005 μm to 0.5 μm. In a case where the temperature during the baking is lower than the above range, crosslinking is insufficient, and it may be difficult to obtain resistance of the formed protective film to a resist solvent or a basic hydrogen peroxide aqueous solution. On the other hand, when the temperature at the time of baking is higher than the range, the protective film may be decomposed by heat.

A resist film is formed directly on the protective film thus formed or over the protective film, with another layer interposed between the resist film and the protective film, and the resist film is then exposed and developed to form a resist pattern.

The exposure is performed through a mask (reticle) for forming a predetermined pattern, and for example, i-rays, KrF excimer laser, ArF excimer laser, extreme ultraviolet rays (EUV), or electron beams (EB) are used. An alkaline developer is used for development, and a development temperature is appropriately selected from 5° C. to 50° C., and a development time is appropriately selected from 10 seconds to 300 seconds. As the alkaline developer, for example, it is possible to use alkaline aqueous solutions such as aqueous solutions of inorganic alkalis such as sodium hydroxide, potassium hydroxide, sodium carbonate, sodium silicate, sodium metasilicate, and ammonia solutions, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, cyclic amines such as pyrrole and piperidine, and other alkaline aqueous solutions. Furthermore, it is also possible to add an appropriate amount of alcohols such as isopropyl alcohol or nonionic-based surfactants to the above alkaline aqueous solutions and use the resultant mixture. Among these, as the developers, it is preferable to use quaternary ammonium salts, and still more preferable to use tetramethylammonium hydroxide and choline. Furthermore, surfactants or other additives can be added to these developers. It is also possible to use a method in which development is performed with an organic solvent such as butyl acetate in place of the alkaline developer and a portion where the alkali dissolution rate of the photoresist is not improved is developed.

Next, the protective film is subjected to dry etching using the formed resist pattern as a mask. At that time, when the inorganic film is formed on the surface of the used semiconductor substrate, the surface of the inorganic film is exposed, and when the inorganic film is not formed on the surface of the used semiconductor substrate, the surface of the semiconductor substrate is exposed.

Further, a desired pattern is formed by wet etching using a semiconductor wet etching solution using the protective film (also the resist pattern when the resist pattern remains on the protective film) after dry etching as a mask.

As the semiconductor wet etching solution, a general chemical liquid for etching a semiconductor wafer can be used, and for example, both an acidic substance and a basic substance can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic hydrogen peroxide water obtained by mixing an organic amine such as ammonia, sodium hydroxide, potassium hydroxide, sodium cyanide, potassium cyanide, or triethanolamine with hydrogen peroxide water to make the pH basic. Specific examples thereof include SC-1 (ammonia-hydrogen peroxide solution). In addition, a substance capable of adjusting a pH to a basic pH, for example, a substance capable of finally adjusting a pH to a basic pH by mixing urea with hydrogen peroxide water and causing thermal decomposition of urea by heating to generate ammonia, can be used as a chemical liquid for wet etching.

Among them, acidic hydrogen peroxide water or basic hydrogen peroxide water is preferable.

These chemical liquids may contain an additive such as a surfactant.

The temperature during use of the semiconductor wet etching solution is desirably 25° C. to 90° C., and more desirably 40° C. to 80° C. The wet etching time is desirably 0.5 minutes to 30 minutes, and more desirably 1 minute to 20 minutes.

### EXAMPLES

Next, the contents of the present invention will be specifically described with reference to Examples, but the present invention is not limited thereto.

The weight average molecular weights of the polymers shown in the following Synthesis Example 1 to Synthesis Example 6 in the present specification are the measurement results by gel permeation chromatography (hereinafter, abbreviated as GPC). In the measurement, a GPC apparatus manufactured by Tosoh Corporation was used, and measurement conditions and the like are as follows:
Column temperature: 40° C.
Solvent: tetrahydroxyfuran (THE)
Flow rate: 1.0 ml/min
Standard sample: polystyrene (manufactured by Tosoh Corporation)

### Synthesis Example 1

A reaction flask was charged with a mixture prepared by addition of 51.0 g of propylene glycol monomethyl ether to 5.0 g of HP-4770 (manufactured by DIC Corporation), 7.4 g of 3,4,5-tris(acetyloxy)benzoic acid (manufactured by FUJIFILM Wako Pure Chemical Corporation), and 0.3 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-1), and the weight average molecular weight Mw thereof measured in terms of polystyrene by GPC was 805.

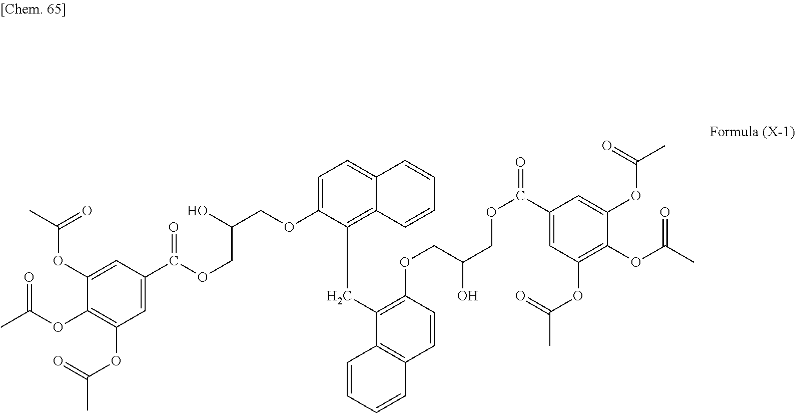 [SMILES: CC(=O)Oc1cc(C(=O)OCC(O)COc2ccc3ccccc3c2Cc2c(OCC(O)COC(=O)c3cc(OC(C)=O)c(OC(C)=O)c(OC(C)=O)c3)ccc3ccccc23)cc(OC(C)=O)c1OC(C)=O]

### Synthesis Example 2

A reaction flask was charged with a mixture prepared by addition of 35.1 g of propylene glycol monomethyl ether to 10.0 g of MeDGIC (product name: MeDGIC, 29.9 mass % propylene glycol monomethyl ether solution, manufactured by Shikoku Chemicals Corporation), 7.2 g of 3,4,5-tris(acetyloxy)benzoic acid (manufactured by FUJIFILM Wako Pure Chemical Corporation), and 0.30 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-2), and the weight average molecular weight Mw thereof measured in terms of polystyrene by GPC was 642.

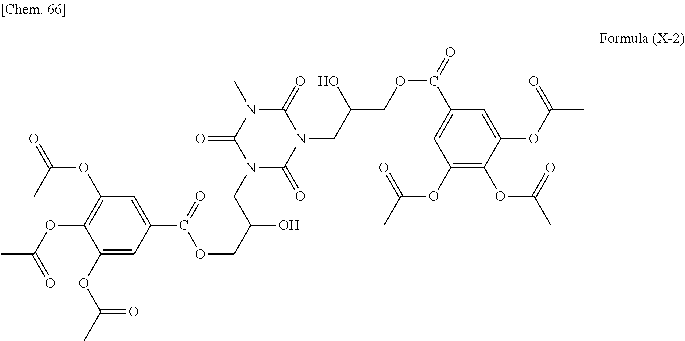 [SMILES: CC(=O)Oc1cc(C(=O)OCC(O)Cn2c(=O)n(C)c(=O)n(CC(O)COC(=O)c3cc(OC(C)=O)c(OC(C)=O)c(OC(C)=O)c3)c2=O)cc(OC(C)=O)c1OC(C)=O]

### Synthesis Example 3

A reaction flask was charged with a mixture prepared by addition of 48.8 g of propylene glycol monomethyl ether to 3.0 g of monoallyl diglycidyl isocyanurate (product name: MA-DGIC, manufactured by Shikoku Chemicals Corporation), 6.5 g of 3,4,5-tris(acetyloxy)benzoic acid (manufactured by FUJIFILM Wako Pure Chemical Co., Ltd.), and 0.3 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-3), and the weight average molecular weight Mw thereof measured in terms of polystyrene by GPC was 755.

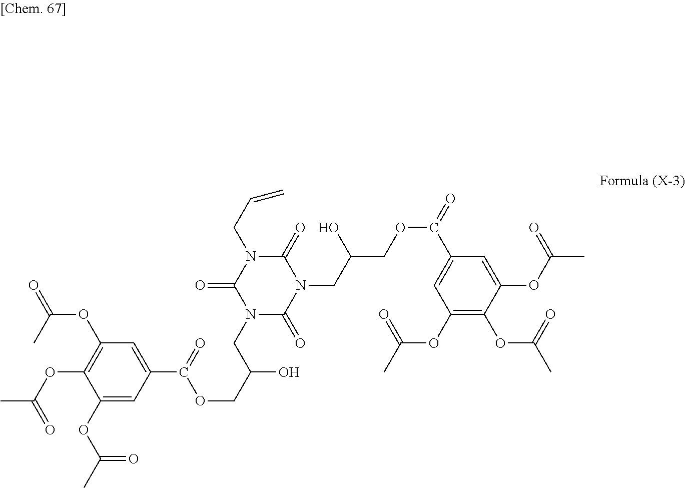 [SMILES: C=CCn1c(=O)n(CC(O)COC(=O)c2cc(OC(C)=O)c(OC(C)=O)c(OC(C)=O)c2)c(=O)n(CC(O)COC(=O)c2cc(OC(C)=O)c(OC(C)=O)c(OC(C)=O)c2)c1=O]

### Synthesis Example 4

A reaction flask was charged with a mixture prepared by addition of 48.8 g of propylene glycol monomethyl ether to 3.0 g of triglycidyl isocyanuric acid (product name: TEPIC, manufactured by Nissan Chemical Corporation), 6.5 g of 3,4,5-tris(acetyloxy)benzoic acid (manufactured by FUJIFILM Wako Pure Chemical Co., Ltd.), and 0.3 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-4), and the weight average molecular weight Mw thereof measured in terms of polystyrene by GPC was 1533.

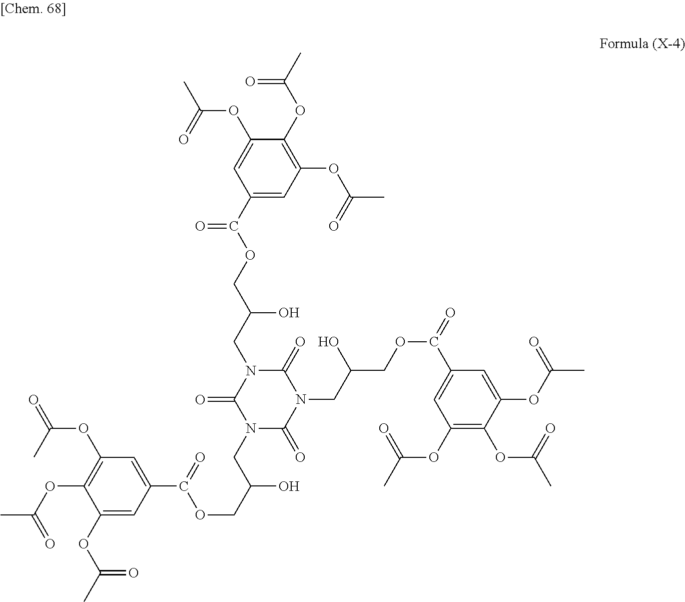 [SMILES: CC(=O)Oc1cc(C(=O)OCC(O)Cn2c(=O)n(CC(O)COC(=O)c3cc(OC(C)=O)c(OC(C)=O)c(OC(C)=O)c3)c(=O)n(CC(O)COC(=O)c3cc(OC(C)=O)c(OC(C)=O)c(OC(C)=O)c3)c2=O)cc(OC(C)=O)c1OC(C)=O]

### Synthesis Example 5

A reaction flask was charged with a mixture prepared by addition of 111.1 g of propylene glycol monomethyl ether to 9.1 g of hydantoin diglycidyl (manufactured by Shikoku Chemicals Corporation), 22.9 g of 3,4,5-tris(acetyloxy)benzoic acid (manufactured by FUJIFILM Wako Pure Chemical Co., Ltd.), and 1.0 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-5), and the weight average molecular weight Mw thereof measured in terms of polystyrene by GPC was 708.

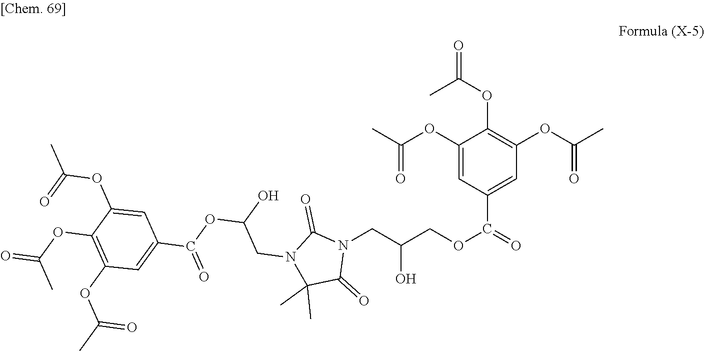 [SMILES: CC(=O)Oc1cc(C(=O)OCC(O)CN2C(=O)N(CC(O)OC(=O)c3cc(OC(C)=O)c(OC(C)=O)c(OC(C)=O)c3)C(C)(C)C2=O)cc(OC(C)=O)c1OC(C)=O]

### Synthesis Example 6

A reaction flask was charged with a mixture prepared by addition of 60.0 g of propylene glycol monomethyl ether to 6.0 g of 2-[4-(2,3-epoxypropoxy)phenyl]-2-(4-[1,1-bis[4-([2,3-epoxypropoxy]phenyl)ethyl]phenyl]propane (manufactured by Nippon Kayaku Co., Ltd., product name: NC-6000) (weight average molecular weight: 548), 8.7 g of 3,4,5-tris(acetyloxy)benzoic acid (manufactured by FUJIFILM Wako Pure Chemical Corporation), and 0.4 g of tetrabutylphosphonium bromide (manufactured by Hokko Chemical Industry Co., Ltd.), and heated and stirred at 100° C. for 16 hours in a nitrogen atmosphere. The obtained reaction product corresponded to Formula (X-6), and the weight average molecular weight Mw thereof measured in terms of polystyrene by GPC was 1998.

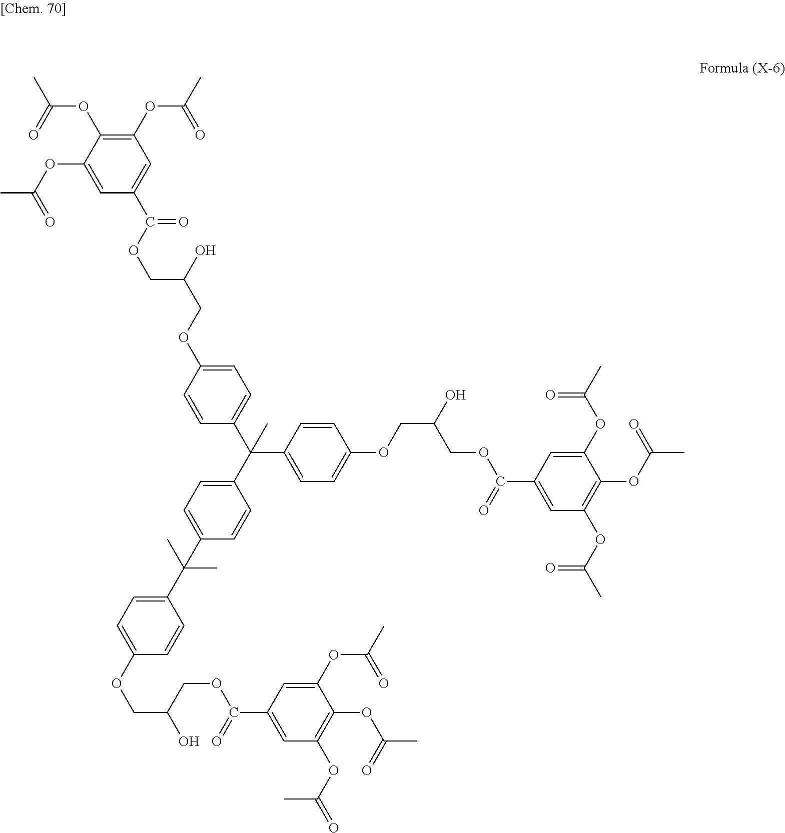 [SMILES: CC(=O)Oc1cc(C(=O)OCC(O)COc2ccc(C(C)(C)c3ccc(C(C)(c4ccc(OCC(O)COC(=O)c5cc(OC(C)=O)c(OC(C)=O)c(OC(C)=O)c5)cc4)c4ccc(OCC(O)COC(=O)c5cc(OC(C)=O)c(OC(C)=O)c(OC(C)=O)c5)cc4)cc3)cc2)cc(OC(C)=O)c1OC(C)=O]

### Synthesis Example 7

A solution (with a solid content of 16.24 mass %) of a reaction product (a copolymer corresponding to the following Formula (In) and having a weight average molecular weight of 4,500 as measured in terms of polystyrene by GPC) obtained by the method described in Synthesis Example 12 of WO2020/026834 was prepared.

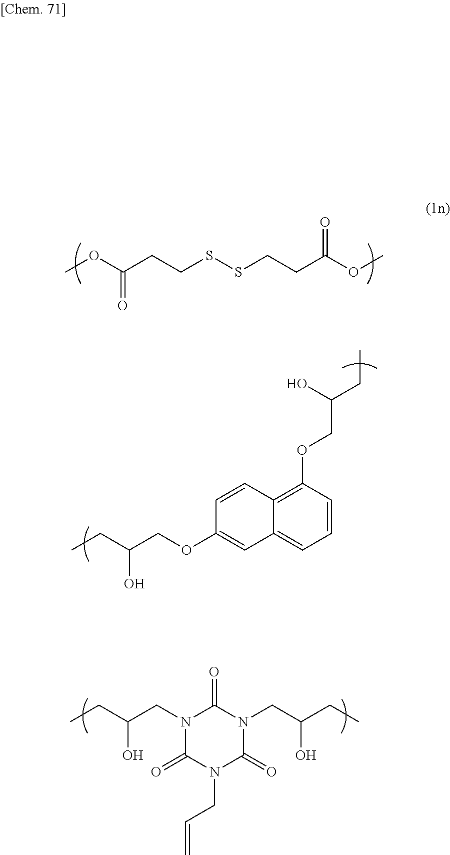

### Example 1

To 4.5 g of a solution (with a solid content of 16.24 mass %) containing the polymer obtained in Synthesis Example 7, 0.028 g of pyridinium trifluoromethanesulfonate (manufactured by Tokyo Chemical Industry Co., Ltd.), 0.037 g of 1,2-diacetoxybenzene (manufactured by Tokyo Chemical Industry Co., Ltd.), 0.0007 g of a surfactant (product name: MEGAFACE R-40, manufactured by DIC Corporation), 1.9 g of propylene glycol monomethyl ether acetate, and 13.5 g of propylene glycol monomethyl ether were added to prepare a solution. The solution was filtered through a polyethylene microfilter having a pore size of 0.02 μm to prepare a protective film-forming composition.

The structure of 1,2-diacetoxybenzene is shown below.

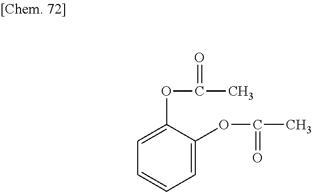

### Example 2

To 4.5 g of a solution (with a solid content of 16.24 mass %) containing the polymer obtained in Synthesis Example 7, 0.028 g of pyridinium trifluoromethanesulfonate (manufactured by Tokyo Chemical Industry Co., Ltd.), 0.28 g of a solution (with a solid content of 13.36 mass %) containing the compound obtained in Synthesis Example 1, 0.0007 g of a surfactant (product name: MEGAFACE R-40, manufactured by DIC Corporation), 1.9 g of propylene glycol monomethyl ether acetate, and 13.3 g of propylene glycol monomethyl ether were added to prepare a solution. The solution was filtered through a polyethylene microfilter having a pore size of 0.02 μm to prepare a protective film-forming composition.

### Example 3

To 4.5 g of a solution (with a solid content of 16.24 mass %) containing the polymer obtained in Synthesis Example (manufactured by Tokyo Chemical Industry Co., Ltd.), 0.27 g of a solution (with a solid content of 13.52 mass %) containing the compound obtained in Synthesis Example 2, 0.0007 g of a surfactant (product name: MEGAFACE R-40, manufactured by DIC Corporation), 1.9 g of propylene glycol monomethyl ether acetate, and 13.3 g of propylene glycol monomethyl ether were added to prepare a solution. The solution was filtered through a polyethylene microfilter having a pore size of 0.02 μm to prepare a protective film-forming composition.

### Example 4

To 4.5 g of a solution (with a solid content of 16.24 mass %) containing the polymer obtained in Synthesis Example 7, 0.028 g of pyridinium trifluoromethanesulfonate (manufactured by Tokyo Chemical Industry Co., Ltd.), 0.28 g of a solution (with a solid content of 13.05 mass %) containing the compound obtained in Synthesis Example 3, 0.0007 g of a surfactant (product name: MEGAFACE R-40, manufactured by DIC Corporation), 1.9 g of propylene glycol monomethyl ether acetate, and 13.2 g of propylene glycol monomethyl ether were added to prepare a solution. The solution was filtered through a polyethylene microfilter having a pore size of 0.02 μm to prepare a protective film-forming composition.

### Example 5

To 4.5 g of a solution (with a solid content of 16.24 mass %) containing the polymer obtained in Synthesis Example 7, 0,028 g of pyridinium trifluoromethanesulfonate (manufactured by Tokyo Chemical Industry Co., Ltd.), 0.26 g of a solution (with a solid content of 13.89 mass %) containing the compound obtained in Synthesis Example 4, 0.0007 g of a surfactant (product name: MEGAFACE R-40, manufactured by DIC Corporation), 1.9 g of propylene glycol monomethyl ether acetate, and 13.3 g of propylene glycol monomethyl ether were added to prepare a solution. The solution was filtered through a polyethylene microfilter having a pore size of 0.02 μm to prepare a protective film-forming composition.

### Example 6

To 4.5 g of a solution (with a solid content of 16.24 mass %) containing the polymer obtained in Synthesis Example 7, 0.028 g of pyridinium trifluoromethanesulfonate (manufactured by Tokyo Chemical Industry Co., Ltd.), 0.26 g of a solution (with a solid content of 13.01 mass %) containing the compound obtained in Synthesis Example 5, 0.0007 g of a surfactant (product name: MEGAFACE R-40, manufactured by DIC Corporation), 1.9 g of propylene glycol monomethyl ether acetate, and 13.2 g of propylene glycol monomethyl ether were added to prepare a solution. The solution was filtered through a polyethylene microfilter having a pore size of 0.02 μm to prepare a protective film-forming composition.

### Example 7

To 4.5 g of a solution (with a solid content of 16.24 mass %) containing the polymer obtained in Synthesis Example 7, 0.028 g of pyridinium trifluoromethanesulfonate (manufactured by Tokyo Chemical Industry Co., Ltd.), 0.26 g of a solution (with a solid content of 14.01 mass %) containing the compound obtained in Synthesis Example 6, 0.0007 g of a surfactant (product name: MEGAFACE R-40, manufactured by DIC Corporation), 1.9 g of propylene glycol monomethyl ether acetate, and 13.2 g of propylene glycol monomethyl ether were added to prepare a solution. The solution was filtered through a polyethylene microfilter having a pore size of 0.02 μm to prepare a protective film-forming composition.

### Comparative Example 1

To 4.5 g of a solution (with a solid content of 16.24 mass %) containing the polymer obtained in Synthesis Example (manufactured by Tokyo Chemical Industry Co., Ltd.), 0.0007 g of a surfactant (product name: MEGAFACE R-40, manufactured by DIC Corporation), and 15.4 g of propylene glycol monomethyl ether were added to prepare a solution. The solution was filtered through a polyethylene microfilter having a pore size of 0.02 μm to prepare a protective film-forming composition.

### (Formation of Coating Film)

### [Resistance Test to Hydrogen Peroxide Water]

As an evaluation of resistance to hydrogen peroxide water, each of the protective film-forming compositions prepared in Examples 1 to 7 and Comparative Example 1 was applied onto a substrate having 50 nm thick titanium nitride (TiN) deposited, and heated at 220° C. for 1 minute to form a protective film having a film thickness of 100 nm.

Next, 20 mass % hydrogen peroxide water was prepared. The TiN deposited substrate applied with the protective film-forming composition was immersed in the 20 mass % hydrogen peroxide water heated to 70° C., and the time from immediately after the immersion until the coating film (protective film) was peeled off was measured. The results of the test for resistance to the hydrogen peroxide water are shown in Table 1. “o” in Table 1 indicates a state in which peeling was not observed in the coating film even after immersion, and “x” indicates a state in which peeling was observed in a part or all of the coating film after immersion.

TABLE 1

| | Result of resistance |
|---|---|
| | test after 2 minutes |
| Example 1 | ○ |
| Example 2 | ○ |
| Example 4 | ○ |
| Example 6 | ○ |
| Example 7 | ○ |
| Comparative | × |
| Example 1 | |

From the results in Table 1 above, it was shown that the coating films produced using the protective film-forming compositions prepared in Examples 1, 2, 4, 6, and 7 have sufficient resistance to the hydrogen peroxide aqueous solution. That is, it was found that these coating films can serve as a protective film against a hydrogen peroxide aqueous solution.

### (Test of Resistance to Basic Hydrogen Peroxide Aqueous Solution)

The coating film prepared on the silicon substrate having the surface on which the titanium nitride film was formed using each of the compositions for forming a protective film prepared in Examples 2 to 5 and Example 7 and the protective film-forming composition prepared in Comparative Example 1 was immersed in a basic hydrogen peroxide aqueous solution having the composition as shown in Table 2 at the temperature shown in the same table for 6 minutes, and then the state of the coating film after being washed with water and dried was visually observed. The results are shown in Table 3 below. “o” in Table 3 indicates a state in which peeling was not observed in the coating film even after immersion, and “x” indicates a state in which peeling was observed in a part or all of the coating film after immersion.

TABLE 2

| 28 mass % | 33 mass % aqueous | | |
|---|---|---|---|
| aqueous ammonia | hydrogen peroxide | Ultrapure | |
| solution | solution | water | Temperature |
| 10 ml | 40 ml | 200 ml | 50° C. |

TABLE 3

| | Result of resistance |
|---|---|
| | test after 6 minutes |
| Example 2 | ○ |
| Example 3 | ○ |
| Example 4 | ○ |
| Example 5 | ○ |
| Example 7 | ○ |
| Comparative | x |
| Example 1 | |

From the results in Table 3 above, it was found that the coating films prepared using the protective film-forming compositions prepared in Examples 2 to 5 and Example 7 had improved resistance to a basic hydrogen peroxide aqueous solution as compared with Comparative Example 1.

### (Test of Optical Parameters)

Each of the protective film-forming compositions prepared in Examples 1 to 7 and Comparative Example 1 was applied onto a silicon wafer with a spinner. Baking was performed on a hot plate at 220° C. for 1 minute to form a resist underlayer film (film thickness: 50 nm). Then, an n value (a refractive index) and a k value (an attenuation coefficient or an absorption coefficient) of these films at a wavelength of 193 nm and a wavelength of 248 nm were measured using a spectroscopic ellipsometer (J. A, Woollam Company, VUV-VASE VU-302). The results are shown in Table 4.

TABLE 4

| | n/k@193 nm | n/k@248 nm |
|---|---|---|
| Example 1 | 1.85/0.24 | 1.75/0.15 |
| Example 2 | 1.82/0.24 | 1.75/0.15 |
| Example 3 | 1.84/0.25 | 1.74/0.14 |
| Example 4 | 1.84/0.25 | 1.74/0.14 |
| Example 5 | 1.84/0.25 | 1.74/0.14 |
| Example 6 | 1.83/0.24 | 1.74/0.14 |
| Example 7 | 1.83/0.26 | 1.74/0.14 |
| Comparative | 1.84/0.24 | 1.74/0.14 |
| Example 1 | | |

### [Evaluation of Etching Selection Ratio]

As an evaluation of the etching selection ratio, each of the resist underlayer film-forming compositions (protective film-forming compositions) prepared in Examples 1 to 7 and Comparative Example 1 described above was applied onto a silicon wafer, and heated at 220° C. for 1 minute to form a protective film having a film thickness of 100 nm. Next, the formed protective film was dry-etched with a mixed gas of nitrogen gas and hydrogen gas using a dry etching apparatus (product name: Lam2300, manufactured by Lam research) to measure a ratio of the dry etching rate of the protective film (selection ratio of the dry etching rate). The measurement results of the etching selection ratio are shown in Table 5. It can be said that the higher the etching selection ratio, the higher the dry etching rate.

TABLE 5

| | Etching selection |
|---|---|
| | ratio |
| | (H2N2 gas |
| | condition) |
| Example 1 | 1.0 |
| Example 2 | 1.0 |
| Example 3 | 1.0 |
| Example 4 | 1.0 |
| Example 5 | 1.0 |
| Example 6 | 1.0 |
| Example 7 | 1.0 |
| Comparative | 1.0 |
| Example 1 | |

From the above results, it can be said that Examples 1 to 7 have almost the same dry etching selection ratio as compared with Comparative Example 1. That is, in Examples 1 to 7, there is no tendency to significantly delay the dry etching time required for removing the protective film.

### INDUSTRIAL APPLICABILITY

The protective film-forming composition according to the present invention provides a protective film having excellent resistance when a wet etching solution is applied in substrate processing.

1. A protective film-forming composition for a semiconductor wet etching solution comprising:
component (A): a film-forming component;
component (B): a compound having an aromatic ring to which an acyloxy group is directly bonded; and
component (C): a solvent.

2. The protective film-forming composition according to claim 1, wherein the component (B) is a compound having an aromatic ring in which two or more acyloxy groups are directly bonded.

3. The protective film-forming composition according to claim 1, wherein the component (B) is a compound having two or more aromatic rings in which two or more acyloxy groups are directly bonded.

4. The protective film-forming composition according to claim 1, wherein the acyloxy group has 2 to 4 carbon atoms.

5. The protective film-forming composition according to claim 1, wherein the aromatic ring is an aromatic hydrocarbon ring.

6. The protective film-forming composition according to claim 1, wherein the component (B) is represented by the following Formula (X-1) or (X-2): 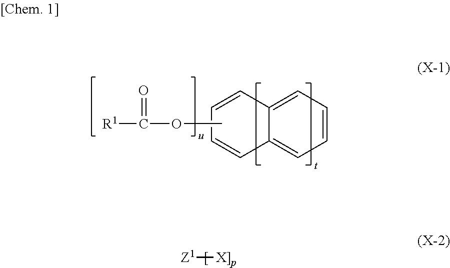
wherein in Formula (X-1), R¹ represents an alkyl group having 1 to 3 carbon atoms, t represents 0 or 1, u represents an integer of 1 to 4, and when there are two or more R¹'s, the two or more R¹'s may be the same or different,
in Formula (X-2), Z¹ represents a p-valent group, p represents an integer of 2 to 4, and X's each independently represent an organic group represented by the following Formula (X-2-1); 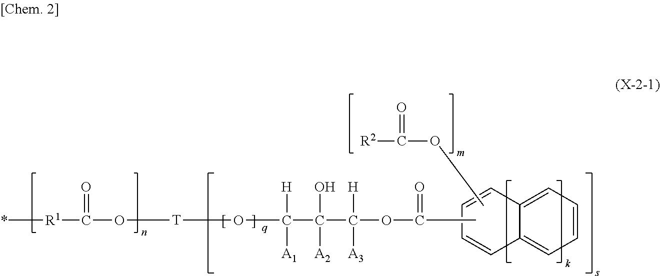
wherein in Formula (X-2-1), R¹ represents a single bond or an alkylene group having 1 to 4 carbon atoms,
R² represents an alkyl group having 1 to 3 carbon atoms,
T represents a single bond or a (s+1)-valent hydrocarbon group having 1 to 8 carbon atoms,
A₁ to A₃ each independently represent a hydrogen atom, a methyl group, or an ethyl group,
k represents 0 or 1,
m represents an integer of 1 to 4,
n represents 0 or 1,
q represents 0 or 1,
s represents 1 or 2,
when there are two or more R²'s, the two or more R²'s may be the same or different, and
* represents a bonding moiety to Z¹ in Formula (X-2),
provided that when T is a single bond, n and q are not simultaneously 1.

7. The protective film-forming composition according to claim 6, wherein Z¹ in Formula (X-2) is represented by the following Formulae (X-2-2) to (X-2-6): 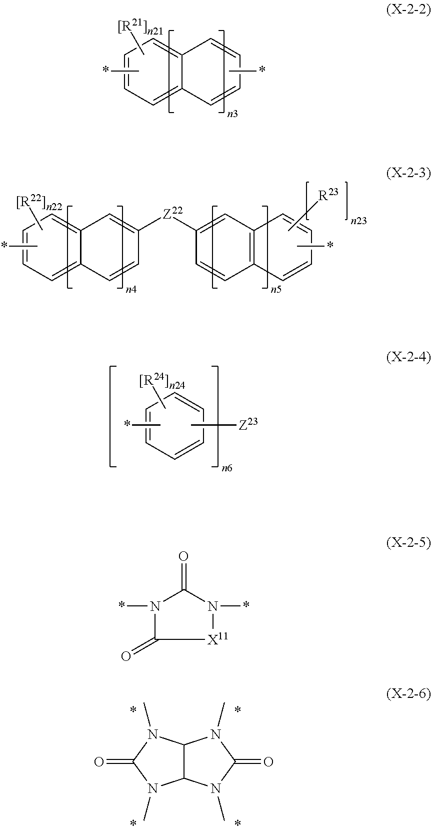
wherein in Formulae (X-2-2) to (X-2-4), R²¹ to R²⁴ each independently represent a halogen atom, a hydroxy group, an alkyl group having 1 to 6 carbon atoms, an alkenyl group having 2 to 6 carbon atoms, an alkynyl group having 2 to 6 carbon atoms, an alkoxy group having 1 to 6 carbon atoms, an alkenyloxy group having 2 to 6 carbon atoms, an alkynyloxy group having 2 to 6 carbon atoms, an acyl group having 2 to 6 carbon atoms, an aryloxy group having 6 to 12 carbon atoms, an arylcarbonyl group having 7 to 13 carbon atoms, or an aralkyl group having 7 to 13 carbon atoms,
in Formula (X-2-2), n3 represents 0 or 1, when n3 is 0, n21 represents an integer of 0 to 4, when n3 is 1, n21 represents an integer of 0 to 6, and when there are two or more R²¹'s, the two or more R²¹'s may be the same or different,
in Formula (X-2-3), Z²² represents a single bond, an oxygen atom, a sulfur atom, a carbonyl group, a sulfonyl group, or an alkylene group having 1 to 6 carbon atoms, n4 and n5 each independently represent 0 or 1, when n4 is 0, n22 represents an integer of 0 to 4, when n4 is 1, n22 represents an integer of 0 to 6, when there are two or more R²²'s, the two or more R²²'s may be the same or different, when n5 is 0, n23 represents an integer of 0 to 4, when n5 is 1, n23 represents an integer of 0 to 6, and when there are two or more R²³'s, the two or more R²³'s may be the same or different,
in Formula (X-2-4), n6 represents 3 or 4, Z²³ represents a n6-valent group, n24 each independently represents an integer of 0 to 4, a plurality of R²⁴'s may be the same or different,
in Formula (X-2-5), X¹¹ represents a group represented by the following Formula (X-2-5-1), the following Formula (X-2-5-2), the following Formula (X-2-5-3), or the following Formula (X-2-5-4), and
* represents a bond to X in Formula (X-2), 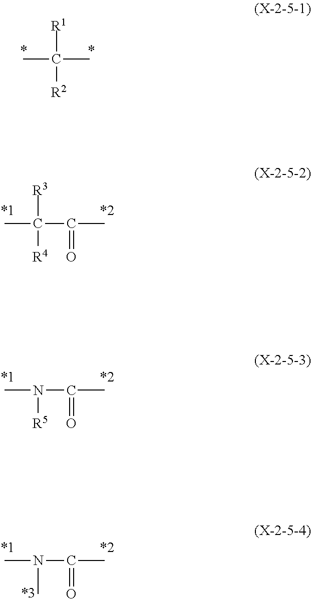
wherein in Formulae (X-2-5-1) to (X-2-5-4),
R¹ to R⁵ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent functional group selected from the group consisting of an alkyl group having 1 to 6 carbon atoms, a halogen atom, an alkoxy group having 1 to 10 carbon atoms, a nitro group, a cyano group, and an alkylthio group having 1 to 6 carbon atoms,
* represents a bond, *1 represents a bond bonded to a carbon atom in Formula (X-2-5), *2 represents a bond bonded to a nitrogen atom in Formula (X-2-5), and *3 represents a bond to X in Formula (X-2).

8. The protective film-forming composition according to claim 1, wherein the component (A) includes a polymer having at least one of a partial structure represented by the following Formula (1), a partial structure represented by the following Formula (2), and a partial structure represented by the following Formula (3): 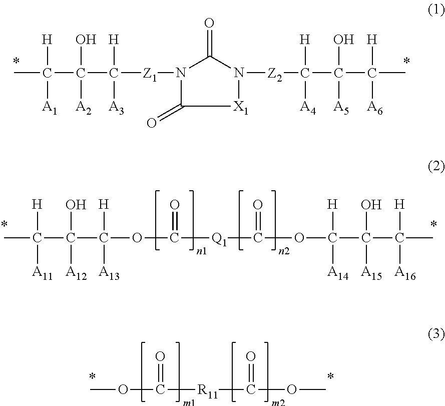
wherein in Formula (1), X₁ represents a divalent group represented by the following Formula (1-1), the following Formula (1-2), or the following Formula (1-3), Z₁ and Z₂ each independently represent a direct bond or a divalent group represented by the following Formula (1-4), A₁, A₂, A₃, A₄, A₅, and A₆ each independently represent a hydrogen atom, a methyl group, or an ethyl group, and * represents a bond,
in Formula (2), Q₁ represents a divalent organic group having an aromatic hydrocarbon ring or an aliphatic hydrocarbon ring, A₁₁, A₁₂, A₁₃, A₁₄, A₁₅, and A₁₆ each independently represent a hydrogen atom, a methyl group, or an ethyl group, n1 and n2 each independently represent 0 or 1, and * represents a bond, and
in Formula (3), R₁₁ represents an organic group having 1 to 30 carbon atoms, m1 and m2 each independently represent 0 or 1, and * represents a bond, 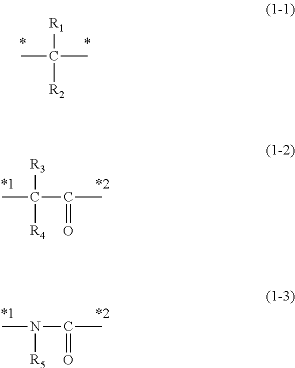
wherein in Formulae (1-1) to (1-3), R₁ to R₅ each independently represent a hydrogen atom, an alkyl group having 1 to 10 carbon atoms which may be interrupted by an oxygen atom or a sulfur atom, an alkenyl group having 2 to 10 carbon atoms which may be interrupted by an oxygen atom or a sulfur atom, an alkynyl group having 2 to 10 carbon atoms which may be interrupted by an oxygen atom or a sulfur atom, a benzyl group, or a phenyl group, and the phenyl group may be substituted with at least one monovalent group selected from the group consisting of an alkyl group having 1 to 6 carbon atoms, a halogen atom, an alkoxy group having 1 to 6 carbon atoms, a nitro group, a cyano group, and an alkylthio group having 1 to 6 carbon atoms, R₁ and R₂ may be bonded to each other to form a ring having 3 to 6 carbon atoms, R₃ and R₄ may be bonded to each other to form a ring having 3 to 6 carbon atoms, * represents a bond, *1 represents a bond bonded to a carbon atom, and *2 represents a bond bonded to a nitrogen atom, 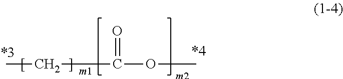
wherein in Formula (1-4), m1 is an integer of 1 to 4, and m2 is 0 or 1, *3 represents a bond bonded to a nitrogen atom, and *4 represents a bond bonded to a carbon atom.

9. A protective film against a semiconductor wet etching solution, wherein the protective film includes a baked product of a coating film formed of the protective film-forming composition according to claim 1.

10. A method for manufacturing a substrate with a protective film which is used in semiconductor manufacturing, the method including: applying the protective film-forming composition according to claim 1 onto a stepped semiconductor substrate and baking the composition to form a protective film.

11. A method for manufacturing a substrate with a resist pattern used in semiconductor manufacturing, the method comprising:
a step of applying the protective film-forming composition according to claim 1 on a semiconductor substrate and baking the protective film-forming composition to form a protective film as a resist underlayer film; and
a step of forming a resist film directly on the protective film or over the protective film, with another layer interlayered, and exposing and developing the resist film to form a resist pattern.

12. A method for manufacturing a semiconductor device, the method comprising a step of forming a protective film by using the protective film-forming composition according to claim 1 on a semiconductor substrate having a surface on which an inorganic film is formed, forming a resist pattern directly on the protective film or over the protective film, with another layer interlayered, dry etching the protective film by using the resist pattern as a mask to expose a surface of the inorganic film, and performing wet etching on the inorganic film by using the protective film after the dry etching as a mask with a semiconductor wet etching solution.
